(19) United States
(12) Patent Application Publication
(10) Pub. No.: US 2016/0064391 A1
(43) Pub. Date: Mar. 3, 2016

(54) DYNAMIC RANDOM ACCESS MEMORY CELL INCLUDING A FERROELECTRIC CAPACITOR

(71) Applicant: QUALCOMM Incorporated, San Diego, CA (US)

(72) Inventors: Xia Li, San Diego, CA (US); Woo Tag Kang, San Diego, CA (US); Changhan Hobie Yun, San Diego, CA (US); Wei-Chuan Chen, Taipei (TW)

(21) Appl. No.: 14/469,341

(22) Filed: Aug. 26, 2014

(51) Int. Cl. H01L 27/115; G11C 11/409; G11C 11/22; H01L 27/108

(52) U.S. Cl. CPC H01L 27/11507; H01L 27/10897; H01L 27/11514; H01L 27/11512; H01L 27/10805; G11C 11/409; G11C 11/221; G11C 11/2273; G11C 11/2275

(57) ABSTRACT

A memory cell includes a capacitor that includes a first metal layer and a second metal layer. The capacitor includes a ferroelectric layer disposed between the first metal layer and the second metal layer. The ferroelectric layer is a single layer of a bi-stable asymmetric crystalline material.

### I. FIELD

The present disclosure is generally related to a dynamic random access memory (DRAM) cell that includes a ferroelectric capacitor.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and Internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

Wireless telephones and other electronic devices may include memory devices to store information. Memory devices may include volatile memory devices (e.g., memory devices that store data so long as a voltage is applied to the memory devices) and non-volatile memory devices (e.g., memory devices that store data regardless of whether voltage is applied to the memory devices). The volatile memory devices may include dynamic random access memory (DRAM) devices. DRAM cells typically include a capacitor for storing a data value and a transistor to enable access to the DRAM cell and are often referred to as “one transistor, one capacitor” (1T1C) cells. The capacitor of the DRAM cell includes a dielectric layer (e.g., an insulator layer with a high dielectric constant k) disposed between two electrodes (e.g., capacitor plates). The capacitor is set to a charged state (e.g., a charge is stored in the electrodes) to represent storage of a first logical value, and the capacitor is discharged to represent storage of a second logical value. When the capacitor is in the charged state, leakage current causes a discharge of the capacitor over time, thus potentially changing a stored logical value.

As semiconductor process and fabrication technologies evolve, the size of components of semiconductors decreases. However, when the electrodes of the capacitor are decreased in size, the amount of charge stored by the electrodes decreases. As the amount of charge stored decreases, the retention time (e.g., an amount of time before discharge of the electrodes) of the capacitor decreases because the decreased amount of charge is discharged faster by the leakage current. If the size of the capacitor becomes too small, the retention time may potentially fall below a retention time threshold.

Additionally, increasing density of a DRAM memory structure with a reduced size is difficult. To increase the density of the DRAM structure, 1T1C DRAM cells are formed using deep trench in silicon formation processes or deep trench in intermetal dielectrics (IMD) formation processes in order to maintain capacitor area. However, the deep trench formation processes of 1T1C cells may not be further scaled to reduced feature sizes due to area limitation associated with the capacitor. Thus, DRAM scaling (e.g., scaling feature sizes of DRAM cells) has slowed down or stopped at the “1× node” (e.g., a semiconductor fabrication process associated with feature sizes between 10-19 nanometers (nm)). For at least this reason, scaling the DRAM structure to semiconductor fabrication processes with smaller process windows while increasing DRAM density is difficult.

### III. SUMMARY

The present disclosure is directed to systems and methods to store logical values (e.g., data values) in DRAM cells that include capacitors having a single ferroelectric layer. In some embodiments, the capacitors may include a high-k layer (e.g., a dielectric layer having a high dielectric constant k). For example, a DRAM cell may include a capacitor that includes a single ferroelectric layer (and a high-k layer) disposed between two metal layers (e.g., electrodes or capacitor plates). The ferroelectric layer may be a single layer of a bi-stable asymmetric crystalline material (e.g., a bi-stable material having an asymmetric crystalline cell structure). For example, the bi-stable asymmetric crystalline material may be hafnium oxide. In at least one embodiment, the hafnium oxide may be doped with Zirconium (Zr), Silicon (Si), Aluminum (Al), or other dopants. The single ferroelectric layer may be a thin film layer, and a capacitor formed using the single ferroelectric layer may have a smaller dimension (e.g., thickness) as compared to other capacitors that include thicker materials, such as lead zirconate titanate (PZT). Due to the smaller thickness, the capacitor including the single ferroelectric layer may be scaled to a semiconductor fabrication process with a process window of 20 nm or less.

A polarization state of the bi-stable asymmetric crystalline material may represent a logical value stored in the capacitor of the DRAM cell. Applying an external electric field (e.g., by applying a voltage to the capacitor) may change the polarization state of the bi-stable asymmetric crystalline material based on an orientation of the external electric field. To illustrate, applying an external electric field having a first orientation may cause an electric dipole of the bi-stable asymmetric crystalline material to align in the first orientation. Applying an external electric field having a second orientation may cause the electric dipole of the bi-stable asymmetric crystalline material to align in the second orientation. The polarization state (e.g., the orientation of the electric dipole) may correspond to (e.g., be equivalent to) a plate charge in other capacitors and may represent storage of a logical value. Because the polarization state is changed by the external electric field (e.g., by applying a voltage to the capacitor) and not by a current through the capacitor, leakage current does not cause the polarization state to change (e.g., degrade). Because the orientation of the electric dipole (e.g., the “ferroelectric dipole”) is not degraded (e.g., changed) by leakage current, dipole charge density of capacitors of the present disclosure may be higher than charge density in capacitors of other DRAM cells (e.g., capacitors that include a high-k layer between two metal plates). Because the charge density is higher and because leakage current does not degrade (e.g., change) the ferroelectric dipole, the capacitors of the present disclosure are able to be scaled to smaller sizes (e.g., at or below the 1× node). Additionally, a retention time (e.g., a holding charge retention time) of the capacitor may be longer (e.g., approximately 10 to 100 times longer) than other capacitors having a similar size. The increased retention time, compared to other capacitors, may enable a DRAM that includes the capacitors to have a lower refresh rate than other DRAM devices, enabling use in lower power applications than for the other DRAM devices.

The DRAM cell may be selected for performance of a read operation or a write operation via a selector included in the DRAM cell. Hence, the DRAM cell may be referred to as a “one selector, one capacitor” (1S1C) DRAM cell. The selector may include a voltage-dependant resistor layer having a nonlinear, voltage-dependent resistance and the selector may be configured to act in a similar manner to a diode. The selector may enable selection or de-selection of the capacitor based on a voltage applied to the selector. In a particular embodiment, the selector may be separate from (e.g., external to) the capacitor and may be coupled to the capacitor. In another particular embodiment, the selector may be integrated within the capacitor (e.g., as one or more layers of the capacitor). When the selector is disposed below the capacitor or is integrated within the capacitor, the selector may not increase a horizontal area occupied by the 1S1C DRAM cell in a semiconductor die. Additionally, multiple 1S1C DRAM cells may be disposed above one another in a “stacked” configuration. In an alternate embodiment, a (1T1C) DRAM cell may include a capacitor with a single layer of bi-stable asymmetric crystalline material (and a high-k layer). Similarly to the 1S1C DRAM cell, leakage current may not degrade (e.g., change) a logical value stored at the bi-stable asymmetric crystalline material of the 1T1C capacitor, and a retention time may be increased and an area of capacitor plates may be reduced (e.g., the capacitor may be further scaled to smaller sizes) as compared to other DRAM cells.

In a particular embodiment, a memory cell includes a capacitor that includes a first metal layer and a second metal layer. The capacitor includes a ferroelectric layer disposed between the first metal layer and the second metal layer. The ferroelectric layer is a single layer of a bi-stable asymmetric crystalline material.

In another particular embodiment, a method includes performing a write operation at a dynamic random access memory (DRAM) cell that includes a capacitor that includes a first metal layer, a second metal layer, and a ferroelectric layer coupled between the first metal layer and the second metal layer. The ferroelectric layer is a single layer of a bi-stable asymmetric crystalline material. The method further includes performing a read operation at the DRAM cell to read a logical value stored at the DRAM cell.

In another particular embodiment, an apparatus includes first conductive means, second conductive means, and means for isolating the first conductive means from the second conductive means. The means for isolating includes a ferroelectric layer that includes a single layer of bi-stable asymmetric crystalline material.

In another particular embodiment, a non-transitory computer readable medium includes instructions that, when executed by a processor, cause the processor to perform a write operation at a dynamic random access memory (DRAM) cell that includes a capacitor that includes a first metal layer, a second metal layer, and a ferroelectric layer coupled between the first metal layer and the second metal layer. The ferroelectric layer is a single layer of a bi-stable asymmetric crystalline material. The instructions, when executed by the processor, further cause the processor to perform a read operation at the DRAM cell to read a logical value stored at a DRAM cell.

One advantage provided by at least one of the disclosed embodiments is a DRAM cell that includes a capacitor that does not lose a stored logical value due to leakage current. Because the logical value is represented by a polarization state of bi-stable asymmetric crystalline material in the ferroelectric layer instead of by a charge stored at the electrodes of the capacitor, leakage current may not cause the logical value to change (e.g., degrade). A size of the capacitor may be reduced as compared to other DRAM capacitors without causing a retention time to potentially fall below a retention time threshold because the retention time is not reduced due to the leakage current. Thus, the capacitor may be scaled to a semiconductor fabrication process with process nodes of 20 nm or less, and the capacitor may have reduced power consumption as compared to other DRAM capacitors. In this manner, a 1T1C DRAM cell formed using the capacitor may have decreased size and increased retention time as compared to other 1T1C DRAM cells. In a particular embodiment, the DRAM cell may include a selector instead of a transistor (e.g., the DRAM cell may be a 1S1C DRAM cell), which may enable the DRAM cell to be “stacked” (e.g., disposed) on or above other 1S1C DRAM cells. Forming multiple 1S1C DRAM cells in a stacked configuration may enable the 1S1C DRAM cells to be included in a memory device having a 3-D memory architecture, which may increase DRAM density of a memory device without increasing a horizontal area occupied by the memory device in a semiconductor die.

Other aspects, advantages, and features of the present disclosure will become apparent after a review of the entire application, including the following sections: Brief Description of the Drawings, Detailed Description, and the Claims.

### IV. BRIEF DESCRIPTION OF THE DRAWINGS

FIG. 1 is a diagram of a first embodiment of a dynamic random-access memory (DRAM) cell including a capacitor that includes a ferroelectric layer of a bi-stable asymmetric crystalline material;

FIG. 2 is a diagram of a second embodiment of a DRAM cell that includes a selector coupled to the capacitor of FIG. 1;

FIG. 3 is a diagram of a third embodiment of a DRAM cell that includes a selector integrated within the capacitor of FIG. 1;

FIG. 4 is a diagram of a fourth embodiment of a DRAM cell that includes a high-k layer within the capacitor of FIG. 1;

FIG. 5 is a diagram of a fifth embodiment of a DRAM cell that includes a high-k layer and a selector layer integrated within the capacitor of FIG. 1;

FIG. 6 is a diagram of a first embodiment of a DRAM cell that is embedded in a semiconductor die;

FIG. 7 is a diagram of a second embodiment of a DRAM cell that is embedded in a semiconductor die;

FIG. 8 is a diagram of a third embodiment of a DRAM cell that is embedded in a semiconductor die;

FIG. 9 is a diagram of a fourth embodiment of a DRAM cell that is embedded in a semiconductor die;

FIG. 10 is a diagram of a fifth embodiment of a DRAM cell that is embedded in a semiconductor die;

FIG. 11 is a diagram of a sixth embodiment of a DRAM cell that is embedded in a semiconductor die;

FIG. 12 is a diagram of a particular illustrative embodiment of performing a write operation to write a logical zero value at the DRAM cell of FIG. 4;

FIG. 13 is a diagram of a particular illustrative embodiment of performing a write operation to write a logical one value at the DRAM cell of FIG. 4;

FIG. 14 is a diagram of a first illustrative embodiment of performing a read operation at the DRAM cell of FIG. 4;

FIG. 15 is a diagram of a second illustrative embodiment of performing a read operation at the DRAM cell of FIG. 4;

FIG. 16 is a diagram of a particular embodiment of a memory array;

FIG. 17 is a flowchart of a particular embodiment of a method of performing a write operation and a read operation at a DRAM cell including a capacitor that includes a single ferroelectric layer of a bi-stable asymmetric crystalline material;

FIG. 18 is a flowchart of a particular method of forming a capacitor that includes a single ferroelectric layer of a bi-stable asymmetric crystalline material; and

FIG. 19 is a diagram of a wireless device including a DRAM device that includes a capacitor with a ferroelectric layer.

### V. DETAILED DESCRIPTION

Particular embodiments of the present disclosure are described below with reference to the drawings. In the description, common features are designated by common reference numbers throughout the drawings.

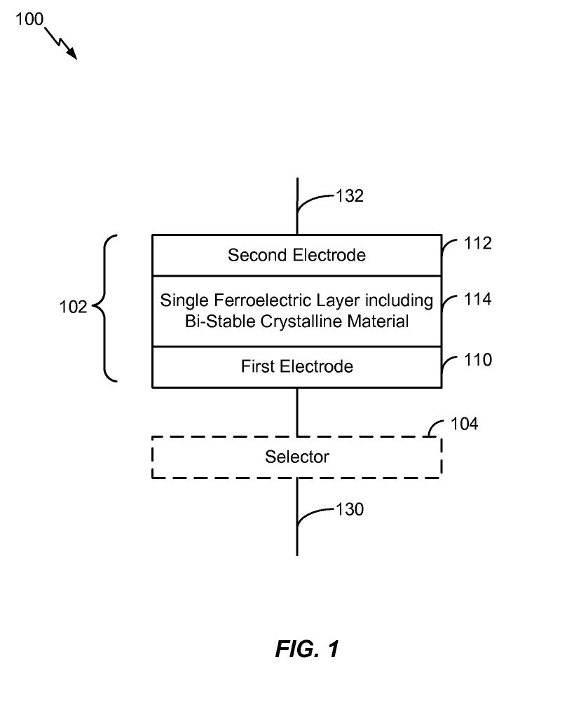

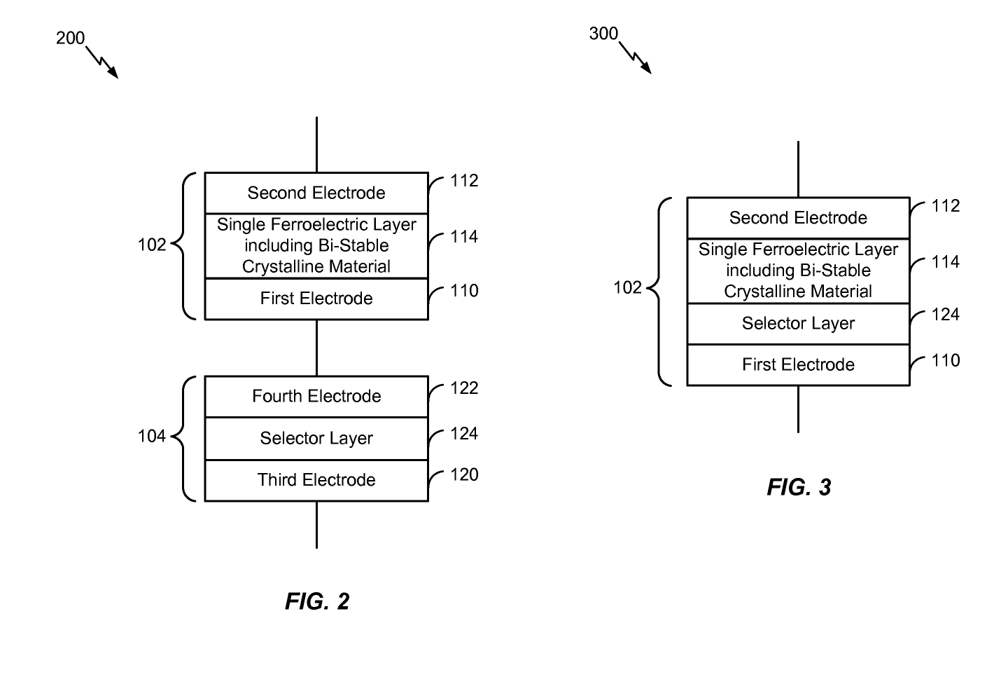

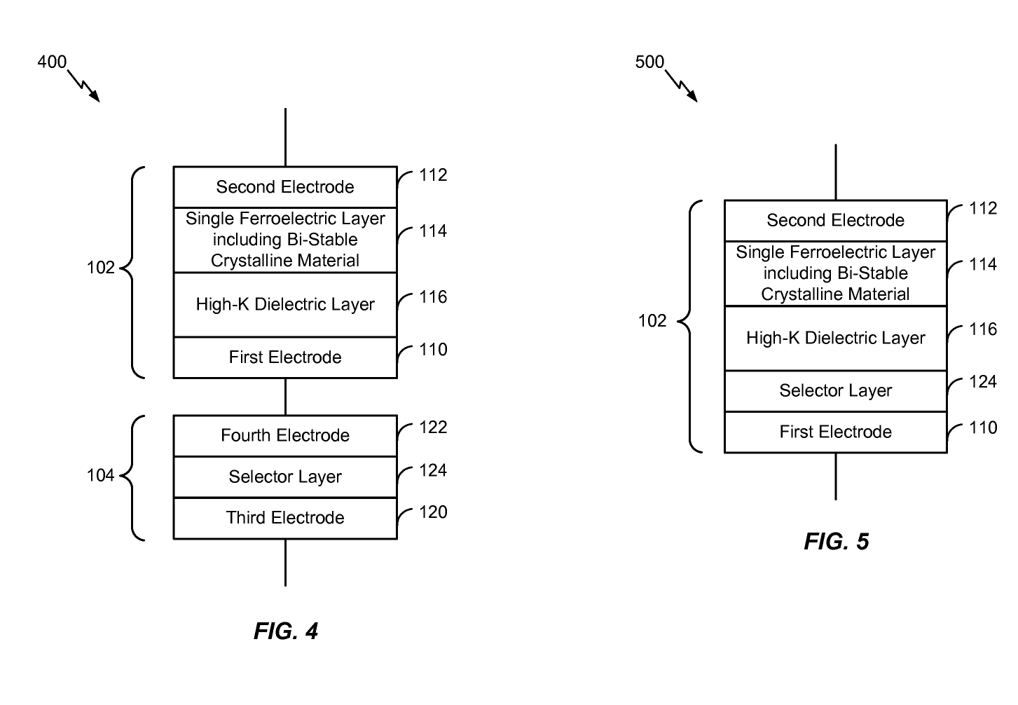

Referring to FIG. 1, a first embodiment of a dynamic random-access memory (DRAM) cell 100 is shown. The DRAM cell 100 may include a capacitor 102 and a selector 104. In some embodiments, the selector 104 may be coupled in series with the capacitor 102, as further described with reference to FIGS. 2 and 3. In other embodiments, the selector 104 may be integrated within the capacitor 102, as further described with reference to FIGS. 4 and 5. In an alternate embodiment, the DRAM cell 100 may include a transistor coupled to the capacitor 102 instead of the selector 104. Multiple DRAM cells having a similar configuration to the DRAM cell 100 may be included in a memory array. In a particular embodiment, the multiple DRAM cells may be included in a cross-point DRAM array.

As shown in FIG. 1, the capacitor 102 may include a first electrode 110 (e.g., a bottom electrode), a second electrode 112 (e.g., a top electrode), and a single ferroelectric layer 114 disposed between the first electrode 110 and the second electrode 112. The first electrode 110 and the second electrode 112 may include a metal, such as copper, titanium (Ti), or tantalum (Ta), or other conductive material, such as titanium nitride (TiN) or tantalum nitride (TaN). The first electrode 110 may be coupled to a first conductor 130 and the second electrode 112 may be coupled to a second conductor 132. In a particular embodiment where the selector 104 is external to the capacitor 102, the selector 104 may be located between the first electrode 110 and the first conductor 130. The first conductor 130 and the second conductor 132 may include conductive wires, such as copper lines or other wires, and may be used to couple the capacitor 102 to bit lines and word lines in a memory array. For example, the first conductor 130 may be coupled to a bit line, and the second conductor 132 may be coupled to a word line.

The single ferroelectric layer 114 may include a single ferroelectric layer of a bi-stable asymmetric crystalline material. For example, the single ferroelectric layer 114 may include a bi-stable ferroelectric material having an asymmetric crystalline structure. In a particular embodiment, the bi-stable asymmetric crystalline material includes hafnium oxide (HfO₂) or doped hafnium oxide. For example, the bi-stable asymmetric crystalline material may include hafnium oxide doped with zirconium (Zr), silicon (Si), aluminum (Al), one or more other dopants, or a combination thereof. The bi-stable asymmetric crystalline material may be formed as a thin film layer. In a particular embodiment, the single ferroelectric layer 114 may be a thin film layer of HfZrO₄, as compared to other ferroelectric capacitors that include multiple, thicker ferroelectric layers of materials such as lead zirconate titanate (PZT) or strontium bismuth tantalate (SBT). For example, the thin film layer of hafnium oxide may have a thickness within a range between 1 nanometer (nm) and 20 nm, as compared to the layers of PZT or SBT, which may have a thickness that exceeds 100 nm. Because the single ferroelectric layer 114 may be a thin film layer, the capacitor 102 may be scaled to a semiconductor fabrication process with process nodes (e.g., feature sizes) of 20 nm or less.

To enable storage of a logical value at the capacitor 102, the bi-stable asymmetric crystalline material of the single ferroelectric layer 114 may be polarized. A polarization state of the bi-stable asymmetric crystalline material may correspond to an orientation of an electric dipole of the bi-stable asymmetric crystalline material. The orientation of the electric dipole may be based on locations of one or more atoms within lattice cells of the bi-stable asymmetric crystalline material. Because the position of the atoms in the lattice cells is asymmetric, an electric dipole may be formed between the atoms. Prior to polarization of bi-stable asymmetric crystalline material (e.g., when the bi-stable asymmetric crystalline material is unpolarized), one or more dipoles may have a substantially random alignment within the bi-stable asymmetric crystalline material such that a net polarization is substantially zero. After polarization of the bi-stable asymmetric crystalline material, the one or more dipoles may align along locations in a first direction (e.g., a “downward” direction) or along locations in a second direction (e.g., an “upward” direction) based on the dipole polarization. For example, when the one or more dipoles align along the downward direction, the electric dipole of the bi-stable asymmetric crystalline material may have a downward orientation, and when the one or more dipoles align along the upward direction, the electric dipole of the bi-stable asymmetric crystalline material may have an upward orientation. The orientation of the electric dipole may correspond to the polarization state of the bi-stable asymmetric crystalline material. For example, a first polarization state may be associated with the electric dipole having the upward orientation, and a second polarization state may be associated with the electric dipole having the downward orientation.

The polarization state (e.g., the orientation of the electric dipole) of the bi-stable asymmetric crystalline material may be changed by an external electric field. In a particular embodiment, the external electric field may be generated via application of a voltage to the capacitor 102. For example, by applying a positive voltage to the capacitor 102, an external electric field having a downward orientation may be applied to the bi-stable asymmetric crystalline material, and by applying a negative voltage to the capacitor 102, an external electric field having an upward orientation may be applied to the bi-stable asymmetric crystalline material. When a magnitude of the applied voltage exceeds a magnitude of a corresponding switching voltage of the bi-stable asymmetric crystalline material of the single ferroelectric layer 114, the polarization state may change. For example, when a positive voltage that exceeds a positive switching voltage is applied to the capacitor 102, the electric dipole may change to the upward orientation and the polarization state may change to the first polarization state. When a magnitude of a negative voltage applied to the capacitor 102 exceeds a magnitude of a negative switching voltage (e.g., when an “absolute value” of the voltage is larger than an “absolute value” of the negative switching voltage), the electric dipole may change to the downward orientation and the polarization state may change to the second polarization state.

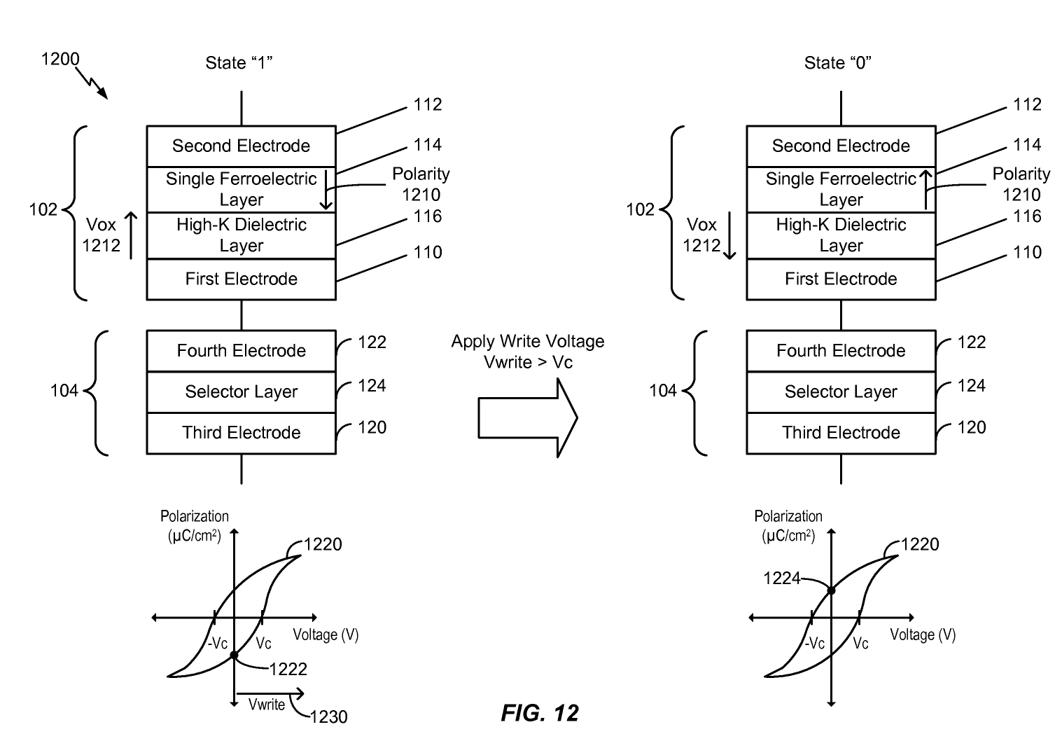

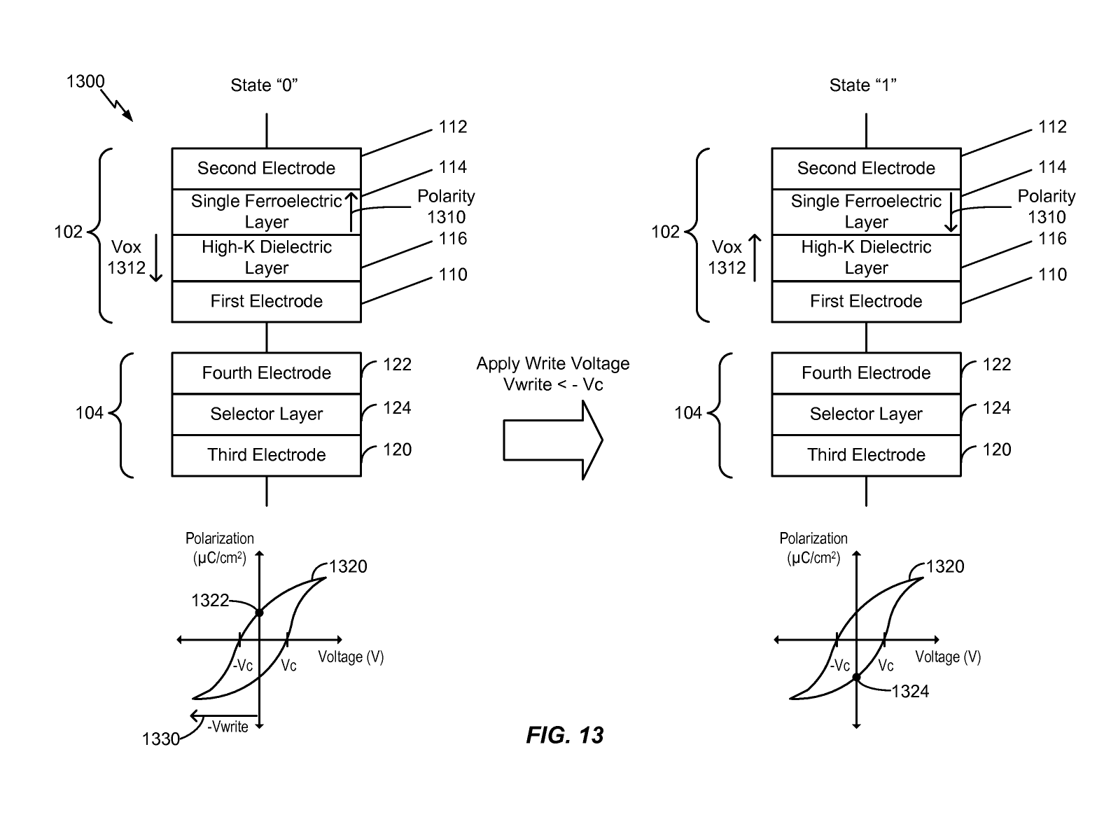

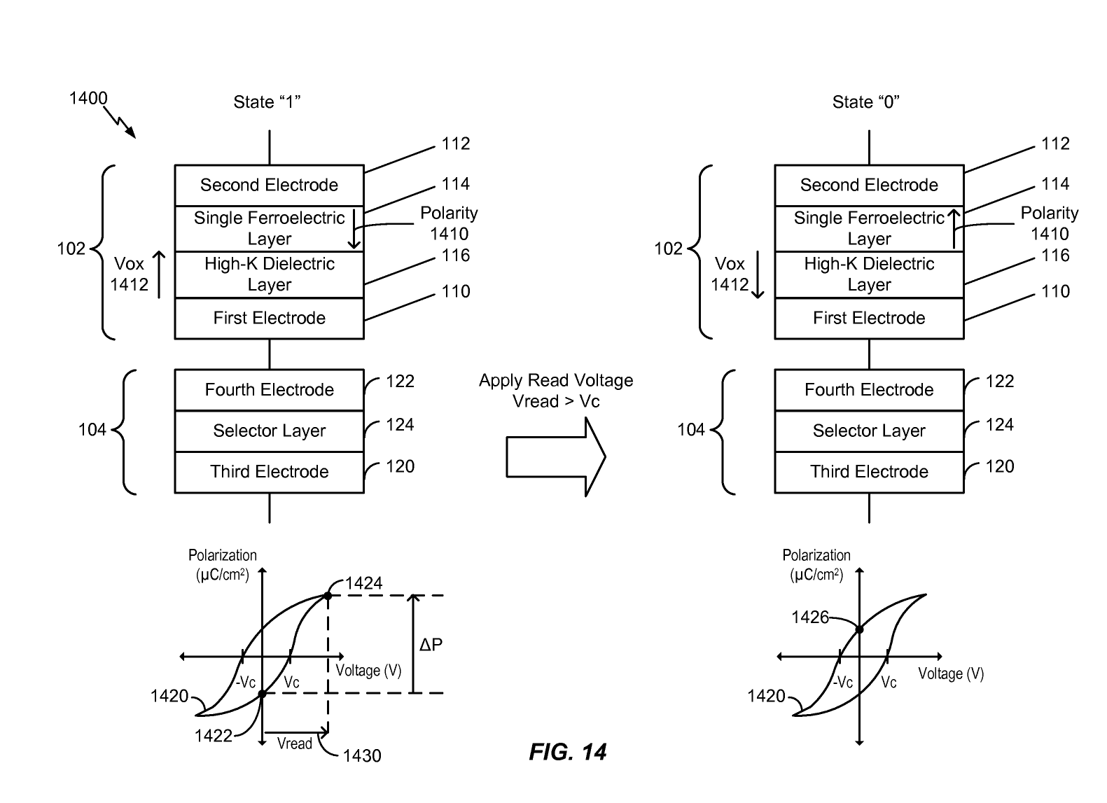

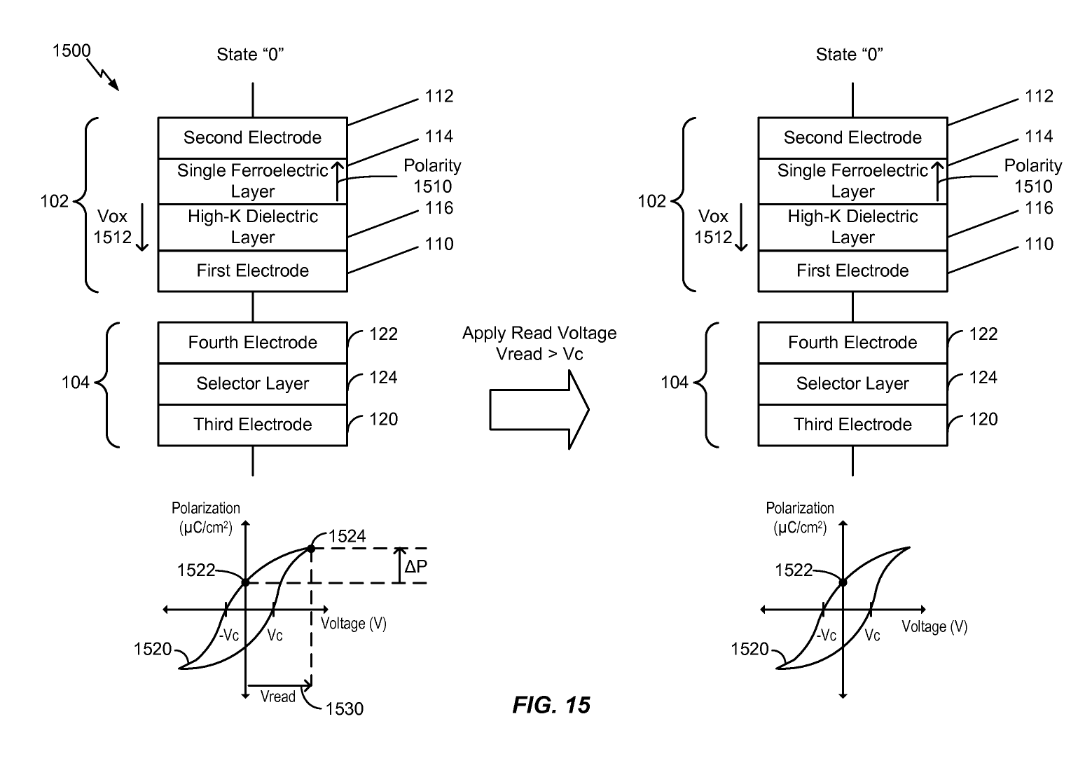

A logical value stored at the capacitor 102 may be represented by the polarization state of the bi-stable asymmetric crystalline material of the single ferroelectric layer 114. For example, the polarization state (e.g., the dipole) of the bi-stable asymmetric crystalline material may induce a charge in the electrodes 110, 112 (e.g., the capacitor plates). In a particular embodiment, the bi-stable asymmetric crystalline material having the first polarization state (e.g., the electric dipole having the upward orientation) may represent storage of a logical zero value at the capacitor 102, and the bi-stable asymmetric crystalline material having the second polarization state (e.g., the electric dipole having the downward orientation) may represent storage of a logical one value at the capacitor 102. In an alternate embodiment, the first polarization state (e.g., the electric dipole having the upward orientation) may be associated with storage of a logical one value and the second polarization state (e.g., the electric dipole having the downward orientation) may be associated with storage of a logical zero value. Performing a write operation at the DRAM cell 100 may include applying a write voltage to the capacitor 102 to set the logical value stored at the capacitor 102 (e.g., to set the polarization state of the bi-stable asymmetric crystalline material) based on the write voltage, as described with reference to FIGS. 12 and 13. The logical value stored in the capacitor 102 may be read by performing a read operation at the DRAM cell 100, as described with reference to FIGS. 14 and 15.

The polarization state is responsive to an external electric field and may be unaffected by a current through the plates of the capacitor 102. For example, the charge in the capacitor plates 110, 112 induced by the dipole of the bi-stable asymmetric crystalline material of the single ferroelectric layer 114 may not be discharged by leakage current. Thus, leakage current may not cause the polarization state of the bi-stable asymmetric crystalline material to change. In other capacitors used in other DRAM cells, leakage current may eventually cause a charge stored on the capacitor plates to be discharged. The discharge may cause a logical value stored at the other capacitors to be lost (e.g., to degrade) over time. As sizes of the other capacitors are decreased (e.g., scaled to semiconductor fabrication processes with smaller process windows), sizes (e.g., areas) of the electrodes of the other capacitors are decreased. Decreasing the areas of the electrodes may decrease an amount of charge that the other capacitors are capable of storing in a charged state. As the amount of stored charge decreases, a time period before the leakage current causes a discharge may decrease. Thus, decreasing the size of the other capacitors may decrease a retention time of the other capacitors. For example, when the other capacitors are scaled to semiconductor fabrication processes with process nodes of 20 nm or less, the retention time of the other capacitors may fall below a retention time threshold, such as 64 microseconds (μs). If the retention time is below the retention time threshold, the other capacitors may not be suitable for use in DRAM.

However, because leakage current does not cause the polarization state (e.g., the orientation of the electric dipole) of the bi-stable asymmetric crystalline material to change, a size of the capacitor 102 may be decreased below a size of the other capacitors while maintaining a retention time that exceeds the retention time threshold of 64 μs. Thus, the capacitor 102 may be scaled to semiconductor fabrication processes with process nodes of 20 nm or less. In some embodiments, the polarization state (e.g., the orientation of the electric dipole) of the bi-stable asymmetric crystalline material of the capacitor 102 may be degraded over time by an external electric field or by a temperature of the capacitor 102. However, an amount of time (e.g., the retention time) before the logical value stored at the capacitor 102 is lost (e.g., degraded) due to the external electric field or the temperature is substantially longer than an amount of time before the other capacitors lose a stored logical value due to leakage current. For example, the capacitor 102 may have a retention time that is 50% longer than a retention time of the other capacitors. In a particular embodiment, the retention time of the capacitor 102 may exceed 64 μs when the capacitor 102 is scaled to semiconductor fabrication processes with process nodes of 20 nm or less. Because DRAM may be periodically refreshed to maintain stored logical values, the loss of the logical value stored at the capacitor 102 due to the external electric field or the temperature may be compensated for by setting a refresh time of the DRAM between the retention time threshold of 64 μs and the retention time of the capacitor 102.

In addition to the capacitor 102, the DRAM cell 100 may include the selector 104. As explained above, the selector 104 may be separate from (e.g., external to) the capacitor 102 or may be integrated within the capacitor 102. The selector 104 may include a voltage-dependent resistor layer having a nonlinear, voltage-dependent resistance. In a particular embodiment, the voltage-dependent resistor layer may include platinum (Pt), tantalum oxide (TaOx), titanium oxide (TiOx), or a combination thereof.

The voltage-dependent resistor layer having a nonlinear, voltage-dependent resistance (e.g., a “voltage-dependent nonlinear resistor layer”) may act in a similar manner to a diode (e.g., a p-n junction diode). For example, the voltage-dependent nonlinear resistor layer may be associated with a non-linear current-voltage (I-V) curve. When a voltage that is less than a particular voltage value is applied to the voltage-dependent nonlinear resistor layer, a very small amount of current may be conducted by the voltage-dependent resistor layer (e.g., a resistance value of the voltage-dependent resistor layer may be very high). When a voltage that is greater than the particular voltage value is applied to the voltage-dependent nonlinear resistor layer, a large amount of current may be conducted by the voltage-dependent resistor layer (e.g., the resistance value may be very low). Accordingly, the resistance of the voltage-dependent nonlinear resistor layer may be nonlinear with reference to voltage and the voltage-dependent nonlinear resistor layer may function similarly to a diode.

The selector 104 may be included in the DRAM cell 100 instead of a transistor, as is typically included in a “one transistor, one capacitor” (1T1C) DRAM cell. The DRAM cell 100 may be selected or deselected based on a voltage applied to the selector 104. For example, when the voltage applied to the selector 104 exceeds the particular voltage value, the DRAM cell 100 may be selected and current flow may be enabled at the DRAM cell 100. When the voltage applied to the selector 104 does not exceed the particular voltage value, the DRAM cell 100 may be unselected or half-selected, and current flow at the DRAM cell 100 may be disabled (e.g., no current flow or a negligible amount of current flow may occur at the DRAM cell 100).

Unlike a transistor, which may include a source region and a drain region formed in a substrate, the selector 104 may be formed outside of the substrate. For example, the selector 104 may be formed within one or more intermetal dielectric (IMD) layers or within one or more interlayer dielectric (ILD) layers of a semiconductor device. Because the selector 104 may be formed outside of the substrate, multiple selectors may be disposed above one another. Thus, a “one selector, one capacitor” (1S1C) DRAM cell, such as the DRAM cell 100, may be disposed in a “stacked” configuration with a second 1S1C DRAM cell.

In this manner, multiple devices may be formed in a stacked configuration in a semiconductor die. For example, a first device may be disposed “above” a second device in a semiconductor device relative to a substrate (e.g., the first device is farther from a surface of the substrate than the second device). At least one of the first device and the second device may be a selector (e.g., a diode). As used herein, a diode may refer to a device that exhibits “diode-type” (e.g., non-linear) I-V characteristics (in a forward bias condition). To illustrate, a first capacitor (e.g., the capacitor 102) may be disposed above a first diode (e.g., the selector 104). A second diode (e.g., a second selector) may be disposed above the first capacitor, and a second capacitor may be disposed above the second diode (e.g., the four devices may be in a stacked configuration). In this embodiment, at least one diode (e.g., the second selector) may be disposed above at least one capacitor (e.g., the first capacitor). Because the first selector, the first capacitor, the second selector, and the second capacitor may have substantially the same horizontal dimensions (e.g., may occupy substantially the same horizontal area in the semiconductor die, where “horizontal” corresponds to a direction along the surface of the substrate, and “vertical” corresponds to a direction perpendicular to the surface of the substrate), disposing the devices in the stacked configuration does not use increased horizontal area in the semiconductor device. Thus, additional selectors and capacitors may be added to the semiconductor die to increase a number of DRAM cells without occupying additional horizontal area in the semiconductor die.

Because 1S1C DRAM cells may be disposed in a stacked configuration, 1S1C DRAM cells may be used in memory devices having three-dimensional (3-D) memory architectures. For example, a first set of 1S1C DRAM cells may be stacked above a second set of 1S1C DRAM cells. In a particular embodiment, 1S1C DRAM cells (including the DRAM cell 100) may be integrated in a memory array having a 3-D architecture. 3-D memory architectures may increase DRAM density without increasing a horizontal area in the semiconductor die occupied by the 1S1C DRAM cells. In contrast, 1T1C memory cells may not be disposed above one another in IMD layers or ILD layers because each transistor is formed partially in a substrate. Because 1T1C memory cells may not be stacked, to increase the density of other DRAMS that include 1T1C DRAM cells, the size of the DRAM cells should be decreased, which is difficult at lower process nodes (e.g., at or below the 1× process node) due to the effects of leakage current on the DRAM cells.

In an alternate embodiment, the DRAM cell 100 may include a transistor instead of the selector 104. In this alternate embodiment, the DRAM cell 100 may be a 1T1C DRAM cell. Because the capacitor 102 includes the single ferroelectric layer 114 including the bi-stable asymmetrical crystalline material, the size of the capacitor 102 may be reduced as compared to capacitors of other DRAM cells. Reducing the size of the capacitor 102 allows a size of the 1T1C DRAM cell (e.g., the DRAM cell 100) to have a reduced size and to consume less power as compared to other 1T1C DRAM cells.

During operation, the DRAM cell 100 may be selected based on a voltage applied to the selector 104. A write operation may be performed by applying a write voltage to the capacitor 102 to set the polarization state (e.g., the orientation of the electric dipole) of the bi-stable asymmetric crystalline material of the single ferroelectric layer 114, as further described with reference to FIGS. 12 and 13. Additionally, or in the alternative, a read operation may be performed by applying a read voltage to the capacitor 102 and sensing an electrical charge pulse from the capacitor 102 during the read operation via a sense amplifier, as further described with reference to FIGS. 14 and 15.

The DRAM cell 100 (e.g., a 1S1C DRAM cell) that includes the capacitor 102 and the selector 104 provides benefits as compared to 1T1C DRAM cells. For example, because the capacitor 102 does not lose a stored logical value due to leakage current, a size of the capacitor 102 may be reduced as compared to other capacitors without decreasing a retention time of the capacitor 102 below a retention time threshold. Thus, the capacitor 102 may be scaled to a semiconductor fabrication process with a process nodes of 20 nm or less. Additionally, because the single ferroelectric layer 114 may be formed using a thin film material (e.g., hafnium oxide), the capacitor 102 may have a reduced thickness as compared to other capacitors that include PZT or SBT. Reducing the thickness of the capacitor 102 may reduce the switching voltages associated with the single ferroelectric layer 114, which may reduce power consumption in the DRAM cell 100 as compared to other DRAM cells. Additionally, because the DRAM cell 100 includes the selector 104 instead of a transistor, the DRAM cell 100 may be used in a memory device having a 3-D memory architecture to increase DRAM density without increasing horizontal area occupied in a semiconductor die.

Referring to FIG. 2, a second embodiment of the DRAM cell of FIG. 1 is shown and designated 200. In the DRAM cell 200, the selector 104 is separate from (e.g., external to) the capacitor 102 and is coupled in series with the capacitor 102. The capacitor 102 is configured as described with reference to FIG. 1.

As illustrated in FIG. 2, the selector 104 may include a third electrode 120 (e.g., a selector bottom electrode), a fourth electrode 122 (e.g., a selector top electrode), and a selector layer 124 disposed between the third electrode 120 and the fourth electrode 122. The selector layer 124 may include a voltage-dependant resistor layer. As described with reference to FIG. 1, the selector layer 124 may function in a similar manner to a diode. The selector layer 124 (e.g., the voltage-dependent resistor layer) may be formed as a film layer and may correspond to an insulator at low voltages. In a particular embodiment, the insulating film may include platinum (Pt), tantalum oxide (TaOx), titanium oxide (TiOx), or a combination thereof. Because the selector layer 124 (e.g., the insulator) may be disposed between two electrodes (e.g., two metal layers), the selector 104 may be a metal-insulator-metal (MIM) device. Additionally, because the selector layer 124 exhibits “diode-type” (e.g., non-linear) I-V characteristics (in a forward bias conditions), the selector 104 may be referred to as a varistor-type bidirectional switch (VBS).

The selector 104 may enable selection of the DRAM cell 200 (e.g., the capacitor 102) based on a voltage applied across the third electrode 120 and the fourth electrode 122. For example, the DRAM cell 200 may be selected when a first voltage (e.g., a “high” voltage that exceeds a particular (e.g., switching) voltage associated with the selector layer 124) is applied across the third electrode 120 and the fourth electrode 122. The DRAM cell 200 may be de-selected when a second voltage (e.g., a “low” voltage that is less than the particular voltage) is applied across the third electrode 120 and the fourth electrode 122. When the DRAM cell 200 is selected, read operations and/or write operations may be performed, as further described with reference to FIGS. 12-15. The selector 104 thus enables performance of the read operations and/or the write operations at the DRAM cell 200 based on a voltage applied to the selector layer 124. FIG. 2 thus illustrates an embodiment of a DRAM cell 200 where the selector 104 is separate from (e.g., external to) the capacitor 102.

Referring to FIG. 3, a third embodiment of the DRAM cell of FIG. 1 is shown and designated 300. In the DRAM cell 300, the selector 104 is integrated within the capacitor 102. The capacitor 102 is configured as described with reference to FIG. 1.

As illustrated in FIG. 3, the selector layer 124 may be disposed between the single ferroelectric layer 114 and the first electrode 110. In a particular embodiment, the selector layer 124 may be in contact with the single ferroelectric layer 114. In an alternate embodiment, an electrode (e.g., a selector top electrode) may be disposed between the selector layer 124 and the single ferroelectric layer 114.

The selector layer 124 may include a voltage-dependant resistor layer. As described with reference to FIG. 1, the selector layer 124 may exhibit diode-type (e.g., non-linear) I-V characteristics (in a forward bias conditions). The selector layer 124 (e.g., the voltage-dependent resistor layer) may be formed as a film layer and may correspond to an insulator at low voltages. In a particular embodiment, the selector layer 124 may include platinum (Pt), tantalum oxide (TaOx), titanium oxide (TiOx), or a combination thereof.

The selector layer 124 may enable selection of the DRAM cell 300 (e.g., the capacitor 102) based on a voltage applied across the first electrode 110 and the second electrode 112. For example, the DRAM cell 300 may be selected when a first voltage (e.g., a “high” voltage that exceeds a particular (e.g., switching) voltage associated with the selector layer 124) is applied across the first electrode 110 and the second electrode 112. The DRAM cell 300 may be de-selected when a second voltage (e.g., a “low” voltage that is less than the particular voltage) is applied across the first electrode 110 and the second electrode 112. When the DRAM cell 300 is selected, read operations and/or write operations may be performed, as further described with reference to FIGS. 12-15. Because the resistance of the selector layer 124 is based on the voltage applied to the capacitor 102 (e.g., across the first electrode 110 and the second electrode 112), the selector layer 124 may apply “self-rectification” to an applied voltage and the DRAM cell 300 may be referred to as a “self-rectifying” DRAM cell.

FIG. 3 thus illustrates an embodiment of a DRAM cell 300 where the selector layer 124 is integrated within the capacitor 102. Integrating the selector layer 124 within the capacitor 102 may enable the DRAM cell 300 to be formed using fewer components (e.g., electrodes) and may reduce a total size of the DRAM cell 300 as compared to the DRAM cell 200 of FIG. 2.

Referring to FIG. 4, a fourth embodiment of the DRAM cell of FIG. 1 is shown and designated 400. In the DRAM cell 400, the selector 104 is separate from (e.g., external to) the capacitor 102 and is coupled in series with the capacitor 102, as described with reference to FIG. 2.

As illustrated in FIG. 4, the capacitor 102 may include a high-k dielectric layer 116. The high-k dielectric layer 116 may include an insulator (e.g., an insulating material) having a high dielectric constant K. For example, the high-k dielectric layer 116 may include an oxide film or other high-k material. The high-k dielectric layer 116 may be adjacent to the single ferroelectric layer 114 and between the first electrode 110 and the second electrode 112. For example, the high-k dielectric layer 116 may be disposed between the single ferroelectric layer 114 and the first electrode 110. Alternatively, the high-k dielectric layer 116 may be disposed between the single ferroelectric layer 114 and the second electrode 112. A dipole of the single ferroelectric layer 114 may induce a charge in the electrodes 110, 112 (e.g., the capacitor plates) and the high-k dielectric layer 116, and the capacitor 102 may store the charge similarly to a traditional DRAM capacitor. However, as explained with reference to FIG. 1, the charge (e.g., the plate charge) induced by the dipole may not be degraded due to leakage current. Including the high-k dielectric layer 116 in the DRAM cell 400 may increase a retention time associated with the DRAM cell 400.

FIG. 4 thus illustrates an embodiment of a DRAM cell 400 where the selector 104 is separate from (e.g., external to) the capacitor 102 and where the capacitor 102 includes a high-k dielectric layer 116. Integrating the high-k dielectric layer 116 within the capacitor 102 may enable the capacitor 102 of the DRAM cell 400 to have a longer retention time as compared to embodiments without the high-k dielectric layer 116.

Referring to FIG. 5, a fifth embodiment of the DRAM cell of FIG. 1 is shown and designated 500. In the DRAM cell 500, the selector layer 124 is integrated within the capacitor 102, as described with reference to FIG. 3. For example, the selector layer 124 is between the first electrode 110 and the second electrode 112.

As illustrated in FIG. 5, the capacitor 102 may include a high-k dielectric layer 116. The high-k dielectric layer 116 may include an insulator (e.g., an insulating material) having a high dielectric constant K. For example, the high-k dielectric layer 116 may include an oxide film or other high-k material. The high-k dielectric layer 116 may be adjacent to the single ferroelectric layer 114 and between the first electrode 110 and the second electrode 112. For example, the high-k dielectric layer 116 may be disposed between the single ferroelectric layer 114 and the selector layer 124. Alternatively, the high-k dielectric layer 116 may be disposed between the single ferroelectric layer 114 and the second electrode 112. A dipole of the single ferroelectric layer 114 may induce a charge in the electrodes 110, 112 (e.g., the capacitor plates) and the high-k dielectric layer 116, and the capacitor 102 may store the charge similarly to a traditional DRAM capacitor. However, as explained with reference to FIG. 1, the charge (e.g., the plate charge) induced by the dipole may not be degraded due to leakage current. Including the high-k dielectric layer 116 in the DRAM cell 500 may increase a retention time associated with the DRAM cell 500.

FIG. 5 thus illustrates an embodiment of a DRAM cell 500 where the selector layer 124 and the high-k dielectric layer 116 are integrated within the capacitor 102. Integrating the high-k dielectric layer 116 within the capacitor 102 may enable the capacitor 102 of the DRAM cell 500 to have a longer retention time than as compared to embodiments without the high-k dielectric layer 116, and integrating the selector layer 124 within the capacitor 102 may enable the DRAM cell 500 to perform “self-rectification,” as described with reference to FIG. 3.

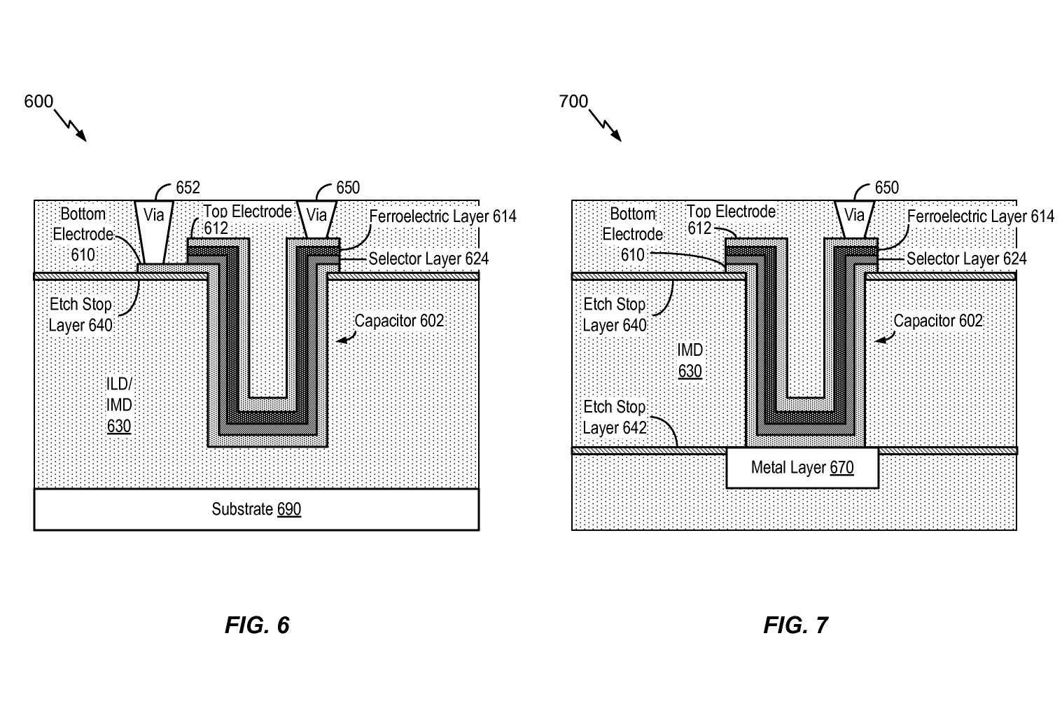

Referring to FIG. 6, a diagram of a first embodiment of a DRAM cell that is embedded in a semiconductor die is illustrated and designated 600. For example, the DRAM cell 600 may be integrated within the same semiconductor die or module as a processor or an application-specific integrated circuit (ASIC). Embedding the DRAM cell 600 within the same semiconductor die as the processor or the ASIC may enable the DRAM cell 600 to be coupled to wider buses and to have higher operating speeds and lower power consumption as compared to a DRAM cell that is formed on a separate semiconductor die from the processor or from the ASIC. For example, the processor or the ASIC and the DRAM cell 600 may be coupled together on the same semiconductor die at lower power and higher speed as compared to being coupled via interfaces between semiconductor dies, which may increase power consumption and may decrease operating speed.

As illustrated in FIG. 6, the DRAM cell 600 may include a capacitor 602. The capacitor 602 may include a bottom electrode 610, a top electrode 612, and a single ferroelectric layer 614 disposed between the top electrode 612 and the bottom electrode 610. The single ferroelectric layer 614 may be similar to the single ferroelectric layer 114 of FIGS. 1-3. For example, the single ferroelectric layer 614 may include a bi-stable asymmetric crystalline material (e.g., hafnium oxide or doped hafnium oxide), and a polarization state of the bi-stable asymmetric crystalline material may represent a logical value stored in the DRAM cell 600, as described with reference to FIG. 1. In some embodiments, the capacitor 602 may include a high-k dielectric layer disposed between the bottom electrode 610 and the single ferroelectric layer 614 or between the single ferroelectric layer 614 and the top electrode 612, such as the high-k dielectric layer 116 of FIGS. 4-5. The capacitor 602 may also include a selector layer 624 disposed between the single ferroelectric layer 614 and the bottom electrode 610. The selector layer 624 may include a voltage-dependent resistor layer and may operate in a similar manner to a diode, as described with reference to FIG. 1.

The capacitor 602 may be formed within a semiconductor die that includes a processor or an ASIC. For example, the semiconductor die may include a substrate 690, an interlayer dielectric (ILD) layer or intermetal dielectric (IMD) layer 630, and an etch stop layer 640. The semiconductor die may also include additional layers and/or components of the processor or the ASIC (not illustrated). In a particular embodiment, the capacitor 602 may be formed within a trench in the ILD/IMD layer 630. In other embodiments, the capacitor 602 may be formed in a trench within multiple ILD/IMD layers separated by multiple etch stop layers. The top electrode 612 may be coupled to a first via 650 and the bottom electrode 610 may be coupled to a second via 652. In a particular embodiment, the first via 650 and the second via 652 may provide conductive paths to a bit line and to a word line, respectively.

During operation, the DRAM cell 600 may operate in a similar manner to the DRAM cell 300 of FIG. 3. For example, a voltage may be applied to the capacitor 602 by applying the voltage to the vias 650 and 652. Based on the applied voltage, the selector layer 624 may select the capacitor 602 and may enable performance of a read operation or a write operation using the applied voltage. The DRAM cell 600 may be “self-rectifying,” as described with reference to FIG. 3.

FIG. 6 thus illustrates an embodiment of the DRAM cell 600 where the capacitor 602 is disposed in the ILD/IMD layer 630 above the substrate 690 and is coupled to the two vias 650 and 652. Thus, the DRAM cell 600 may be integrated within a semiconductor die that includes a processor or an ASIC. Integrating the DRAM cell 600 in the semiconductor die with the processor or the ASIC enables the DRAM cell 600 to experience benefits such as wider buses and higher operation speeds, as compared to a DRAM cell that is formed on a separate semiconductor die from the processor or the ASIC.

Referring to FIG. 7, a diagram of a second embodiment of a DRAM cell that is embedded within a semiconductor die is illustrated and designated 700. The DRAM cell 700 may be integrated within the same semiconductor die or module as a processor or an ASIC, as described with reference to FIG. 6. The DRAM cell 700 may include the capacitor 602 of FIG. 6. In some embodiments, the capacitor 602 may include a high-k dielectric layer disposed between the bottom electrode 610 and the single ferroelectric layer 614 or between the single ferroelectric layer 614 and the top electrode 612, such as the high-k dielectric layer 116 of FIGS. 4-5.

As illustrated in FIG. 7, the capacitor 602 may be formed in an IMD layer 630. In this embodiment, the IMD layer 630 may be any IMD layer. For example, the IMD layer 630 may be between two metal layers and there may be multiple layers between the IMD layer 630 and a substrate of the semiconductor die. Although illustrated as being formed in the IMD layer 630 (e.g., between the etch stop layers 640 and 642), in other embodiments the capacitor 602 may be formed in multiple IMD layers. The top electrode 612 may be coupled to a first via 650 and the bottom electrode 610 may be coupled to a metal layer 670. In a particular embodiment, the first via 650 and the metal layer 670 may provide conductive paths to a bit line and to a word line, respectively. Thus, FIG. 7 illustrates an embodiment of the DRAM cell 700 that is accessible from the bottom (e.g., via the metal layer 670) and from the top (e.g., via the first via 650).

Referring to FIG. 8, a diagram of a third embodiment of a DRAM cell that is embedded within a semiconductor die is illustrated and designated 800. The DRAM cell 800 may be integrated within the same semiconductor die or module as a processor or an ASIC, as described with reference to FIG. 6. The DRAM cell 800 may be similar to the DRAM cell 600 of FIG. 6. However, in the embodiment of FIG. 8, the capacitor 602 may also include a selector top electrode 626 disposed between the single ferroelectric layer 614 and the selector layer 624. In some embodiments, the capacitor 602 may include a high-k dielectric layer disposed between the selector top electrode 626 and the single ferroelectric layer 614 or between the single ferroelectric layer 614 and the top electrode 612, such as the high-k dielectric layer 116 of FIGS. 4-5. Each of the bottom electrode 610, the top electrode 612, and the selector top electrode 626 may be independently biasable. For example, an additional via may be coupled to the selector top electrode 626 and may provide a conductive path to a conductive line to enable biasing of the selector top electrode 626. Including the selector top electrode 626 in the capacitor 602 may enable the selector layer 624 to be responsive to a voltage applied across the selector top electrode 626 and the bottom electrode 610, instead of a voltage applied across the top electrode 612 and the bottom electrode 610. Because the selector layer 624 is not responsive to the voltage applied across the top electrode 612 and the bottom electrode 610 (e.g., a read voltage or a write voltage), the DRAM cell 800 enables greater control of selection or non-selection of the DRAM cell 800.

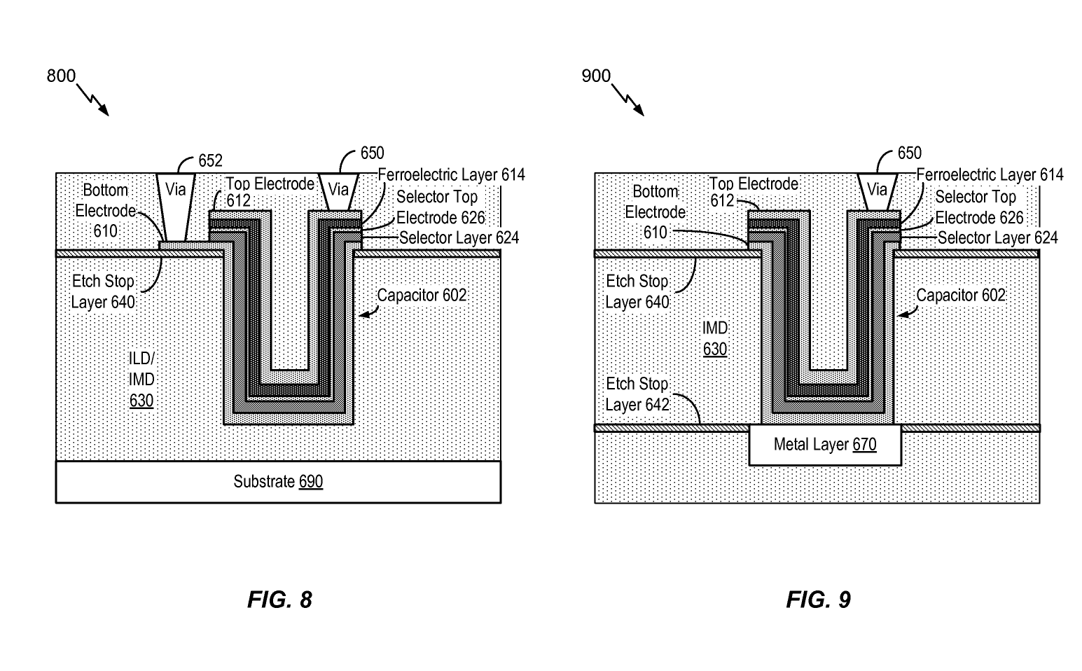

Referring to FIG. 9, a diagram of a fourth embodiment of a DRAM cell that is embedded within a semiconductor die is illustrated and designated 900. The DRAM cell 900 may be integrated within the same semiconductor die or module as a processor or an ASIC, as described with reference to FIG. 6. The DRAM cell 900 may be similar to the DRAM cell 700 of FIG. 7. However, in the embodiment of FIG. 9, the capacitor 602 may also include the selector top electrode 626 disposed between the single ferroelectric layer 614 and the selector layer 624 and that is biasable independent of the bottom electrode 610 and the top electrode 612. In some embodiments, the capacitor 602 may include a high-k dielectric layer disposed between the selector top electrode 626 and the single ferroelectric layer 614 or between the single ferroelectric layer 614 and the top electrode 612, such as the high-k dielectric layer 116 of FIGS. 4-5. Thus, FIG. 9 illustrates an embodiment of the DRAM cell 900 that enables greater control of selection or non-selection of the DRAM cell 900 and that is accessible from the bottom (e.g., via the metal layer 670) and from the top (e.g., via the first via 650).

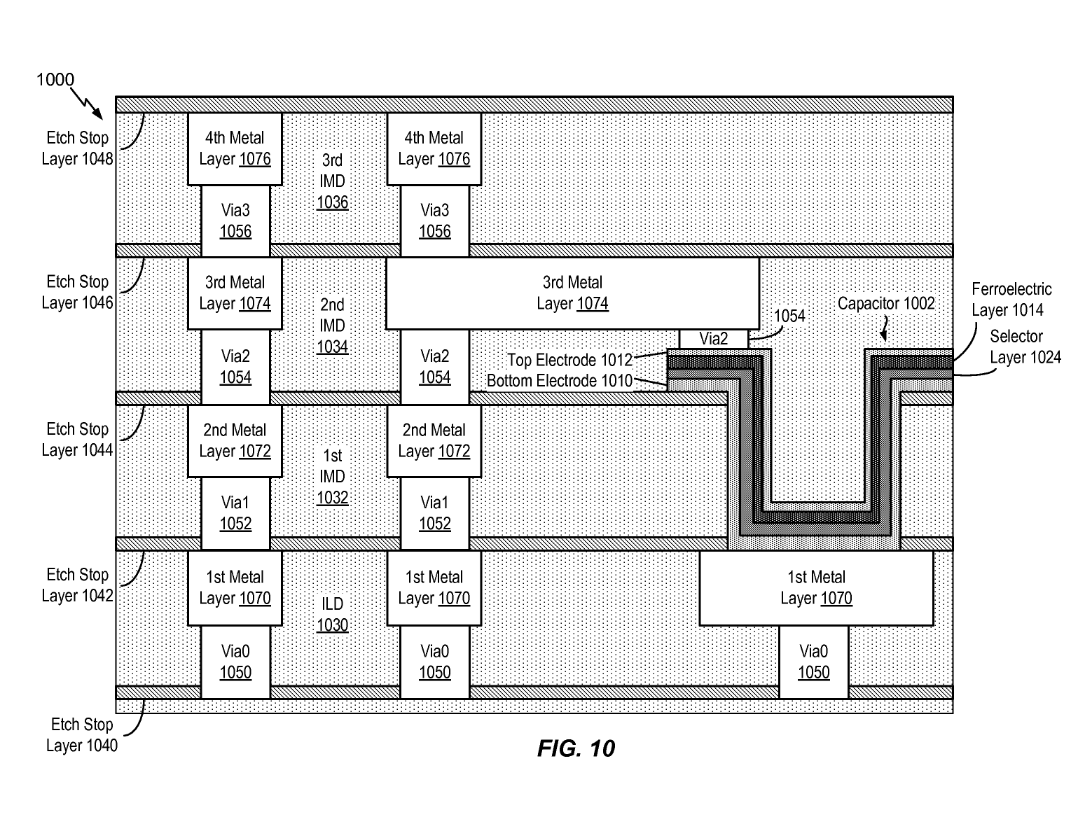

Referring to FIG. 10, a diagram of a fifth embodiment of a DRAM cell that is embedded within a semiconductor die is illustrated and designated 1000. The DRAM cell 1000 may be integrated within the same semiconductor die or module as a processor or an ASIC, as described with reference to FIG. 6. The DRAM cell 1000 may be similar to the DRAM cell 700 of FIG. 7. For example, a capacitor 1002 of the DRAM cell 1000 may correspond to the capacitor 602 of FIG. 7, and bottom electrode 1010, top electrode 1012, single ferroelectric layer 1014, and selector layer 1024 may correspond to the bottom electrode 610, the top electrode 612, the single ferroelectric layer 614, and the selector layer 624 of FIG. 7, respectively. In some embodiments, the capacitor 1002 may include a high-k dielectric layer disposed between the bottom electrode 1010 and the single ferroelectric layer 1014 or between the single ferroelectric layer 1014 and the top electrode 1012, such as the high-k dielectric layer 116 of FIGS. 4-5. However, in the embodiment of FIG. 10, the capacitor 1002 may be disposed in a semiconductor die that includes multiple metal layers and multiple IMD layers. For example, the semiconductor die may include four metal layers 1070-1074, four via layers 1050-1056, an ILD layer 1030, and three IMD layers 1032-1036. The ILD layer 1030 and the IMD layers 1032-1036 may be separated by multiple etch stop layers 1040-1048. As illustrated in FIG. 10, the bottom electrode 1010 may be coupled to a first metal layer 1070, and the top electrode 1012 may be coupled to a third metal layer 1074 via a second via layer 1054. In a particular embodiment, the third metal layer 1074 and the first metal layer 1070 may provide conductive paths to a bit line and to a word line, respectively.

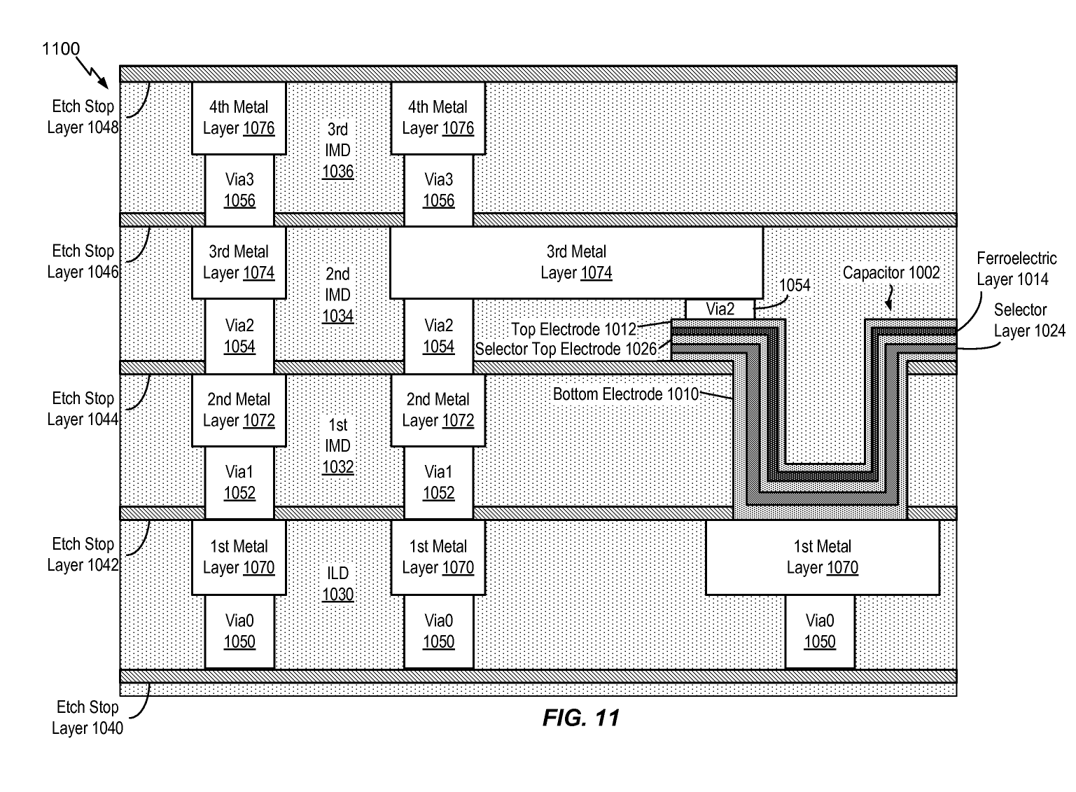

Referring to FIG. 11, a diagram of a sixth embodiment of a DRAM cell that is embedded within a semiconductor die is illustrated and designated 1100. The DRAM cell 1100 may be integrated within the same semiconductor die or module as a processor or an ASIC, as described with reference to FIG. 6. The DRAM cell 1100 may be similar to the DRAM cell 1000 of FIG. 10. However, in the embodiment of FIG. 11, the capacitor 1002 may also include a selector top electrode 1026 disposed between the single ferroelectric layer 1014 and the selector layer 1024. In some embodiments, the capacitor 1002 may include a high-k dielectric layer disposed between the selector top electrode 1026 and the single ferroelectric layer 1014 or between the single ferroelectric layer 1014 and the top electrode 1012, such as the high-k dielectric layer 116 of FIGS. 4-5. The selector top electrode 1026 may be biasable independent of the bottom electrode 1010 and the top electrode 1012 (e.g., using an additional via coupled to the selector top electrode 1026). Including the selector top electrode 1026 in the capacitor 1002 may enable the selector layer 1024 to be responsive to a voltage applied across the selector top electrode 1026 and the bottom electrode 1010, instead of a voltage applied across the top electrode 1012 and the bottom electrode 1010. Because the selector layer 1024 may be controlled (e.g., biased) independently, the DRAM cell 1100 may enable greater control of selection or non-selection of DRAM cell 1100, as compared to the DRAM cell 1000.

Referring to FIG. 12, a diagram of a particular illustrative embodiment of performing a write operation to write a logical zero value at the DRAM cell 400 of FIG. 4 is shown and designated 1200. Although performance of the write operation is described with respect to the DRAM cell 400 of FIG. 4, in other embodiments the write operation may be performed on any of the DRAM cells 100-1100 of FIGS. 1-11.

As illustrated in FIG. 12, the capacitor 102 may store a logical one value prior to performance of the write operation. For example, the bi-stable asymmetric crystalline material of the single ferroelectric layer 114 may be polarized in the second polarization state associated with the electric dipole of the bi-stable asymmetric crystalline material having a downward orientation, as indicated by the downward orientation of the polarity 1210. When the polarity 1210 has the downward orientation, a voltage Vox 1212 across the high-k dielectric layer 116 may have a negative value, as indicated by the upward direction of Vox 1212 in FIG. 12 prior to performance of the write operation. In other embodiments, the capacitor 102 may store a logical zero value prior to performance of the write operation.

During the write operation, a write voltage Vwrite 1230 that exceeds a positive switching voltage Vc of the bi-stable asymmetric crystalline material may be applied to the capacitor 102. In a particular embodiment, the bi-stable asymmetric crystalline material of the single ferroelectric layer 114 may be associated with a hysteresis curve 1220. As illustrated in FIG. 12, a horizontal axis may represent voltage (e.g., a voltage applied to the capacitor 102) and a vertical axis may represent polarization of the bi-stable asymmetric crystalline material of the single ferroelectric layer 114. Application of Vwrite 1230 may shift the polarization of the bi-stable asymmetric crystalline material from a polarization state 1222 representing storage of the logical one value. For example, application of Vwrite 1230 may shift the polarization to the right along the hysteresis curve 1220. Because Vwrite 1230 exceeds the positive switching voltage Vc, application of Vwrite 1230 causes the bi-stable asymmetric crystalline material to change polarization states and to settle, after the write operation, at a polarization state 1224 representing storage of a logical zero value. For example, applying Vwrite 1230 that exceeds the positive switching voltage Vc may cause the electric dipole of the bi-stable asymmetric crystalline material to change orientations to an upward orientation. As illustrated in FIG. 12, after application of Vwrite 1230 (e.g., after performing the write operation), the polarity 1210 has the upward orientation and the voltage Vox has a positive value, as indicated by the downward direction of Vox.

FIG. 12 thus illustrates an embodiment 1200 of performing a write operation to write a logical zero value at the DRAM cell 400 of FIG. 4. Because the write operation may change a polarization state of the bi-stable asymmetric crystalline material of the single ferroelectric layer 114, the logical zero value written by the write operation may not be lost over time due to leakage current.

Referring to FIG. 13, a diagram of a particular illustrative embodiment of performing a write operation to write a logical one value at the DRAM cell 400 of FIG. 4 is shown and designated 1300. Although performance of the write operation is described with respect to the DRAM cell 400 of FIG. 4, in other embodiments the write operation may be performed on any of the DRAM cells 100-1100 of FIGS. 1-11.

As illustrated in FIG. 13, the capacitor 102 may store a logical zero value prior to performance of the write operation. For example, the bi-stable asymmetric crystalline material of the single ferroelectric layer 114 may be polarized in the first polarization state associated with the electric dipole of the bi-stable asymmetric crystalline material having an upward orientation, as indicated by the upward orientation of the polarity 1310. When the polarity 1310 has the upward orientation, a voltage Vox 1312 across the high-k dielectric layer 116 may have a positive value, as indicated by the downward direction of Vox 1312 in FIG. 13 prior to performance of the write operation. In other embodiments, the capacitor 102 may store a logical one value prior to performance of the write operation.

During the write operation, a write voltage Vwrite 1330 that is less than a negative switching voltage −Vc of the bi-stable asymmetric crystalline material may be applied to the capacitor 102. In a particular embodiment, the bi-stable asymmetric crystalline material of the single ferroelectric layer 114 may be associated with a hysteresis curve 1320. As illustrated in FIG. 13, a horizontal axis may represent voltage (e.g., a voltage applied to the capacitor 102) and a vertical axis may represent polarization of the bi-stable asymmetric crystalline material of the single ferroelectric layer 114. Application of Vwrite 1330 may shift the polarization of the bi-stable asymmetric crystalline material from a polarization state 1322 representing storage of the logical zero value. For example, application of Vwrite 1330 may shift the polarization to the left along the hysteresis curve 1320. Because Vwrite 1330 is less than the negative switching voltage −Vc (e.g., the magnitude of Vwrite 1330 is greater than the magnitude of the negative switching voltage −Vc), application of Vwrite 1330 causes the bi-stable asymmetric crystalline material to change polarization states and to settle, after the write operation, at a polarization state 1324 representing storage of a logical one value. For example, applying Vwrite 1330 that is less than the negative switching voltage −Vc may cause the electric dipole of the bi-stable asymmetric crystalline material to change orientations to a downward orientation. As illustrated in FIG. 13, after application of Vwrite 1330 (e.g., after performing the write operation), the polarity 1310 has the downward orientation and the voltage Vox has a negative value, as indicated by the upward direction of Vox.

FIG. 13 thus illustrates an embodiment 1300 of performing a write operation to write a logical one value at the DRAM cell 400 of FIG. 4. Because the write operation may change a polarization state of the bi-stable asymmetric crystalline material of the single ferroelectric layer 114, the logical one value written by the write operation may not be lost over time due to leakage current.

Referring to FIG. 14, a diagram of a first illustrative embodiment of performing a read operation at the DRAM cell 400 of FIG. 4 is shown and designated 1400. Although performance of the read operation is described with respect to the DRAM cell 400 of FIG. 4, in other embodiments the read operation may be performed on any of the DRAM cells 100-1100 of FIGS. 1-11.

In a particular embodiment, the capacitor 102 may store a logical one value prior to performance of the read operation. For example, the bi-stable asymmetric crystalline material of the single ferroelectric layer 114 may be polarized in the second polarization state associated with the electric dipole of the bi-stable asymmetric crystalline material having a downward orientation, as indicated by the downward orientation of the polarity 1410. When the polarity 1410 has the downward orientation, a voltage Vox 1412 across the high-k dielectric layer 116 may have a negative value, as indicated by the upward direction of Vox 1412 in FIG. 14 prior to performance of the read operation.

The logical value stored at the capacitor 102 prior to performing the read operation may be determined by sensing a change in charge (ΔQ) (e.g., a charge pulse) at the capacitor 102 during the read operation. A sense amplifier may be coupled to the capacitor 102 and to the selector 104 and may be configured to sense ΔQ during the read operation. In a particular embodiment, ΔQ may be based on a change in polarity (ΔP) of the bi-stable asymmetric crystalline material of the single ferroelectric layer 114 multiplied by an area (A) of the capacitor 102 (e.g., ΔQ approximates ΔP×A). ΔQ may be used as an indication of ΔP, which may indicate the logical value stored at the capacitor 102 prior to performance of the read operation, as further described below and with reference to FIG. 15.

During the read operation in FIG. 14, a read voltage Vread 1430 that exceeds a positive switching voltage Vc of the bi-stable asymmetric crystalline material may be applied to the capacitor 102. Application of Vread 1430 may shift the polarization of the bi-stable asymmetric crystalline material along a hysteresis curve 1420 from a polarization state 1422 representing storage of the logical one value to a temporary polarization state 1424. Shifting from the polarization state 1422 to the temporary polarization state 1424 may be associated with a large ΔP value, as illustrated in FIG. 14, because Vread 1430 exceeds the positive switching voltage Vc. After Vread 1430 is applied, the polarization may settle at the polarization state 1426 associated with storage of a logical zero value. For example, after application of Vread 1430 (e.g., after performing the read operation), the polarity 1410 has the upward orientation (e.g., the electric dipole of the bi-stable asymmetric crystalline material has an upward direction) and the voltage Vox has a positive value, as indicated by the downward direction of Vox.

Because application of Vread 1430 causes the polarization state of the bi-stable asymmetric crystalline material to change, a large ΔP value may be associated with performing the read operation on a DRAM cell that stores a logical one value. Due to the large ΔP value, the sense amplifier may sense a large ΔQ value during performance of the read operation. The ΔQ value sensed by the sense amplifier may be compared to a preprogrammed or threshold ΔQ value associated with a change in polarization states to determine whether a logical one value was stored at the capacitor 102 prior to performance of the read operation. For example, a sensed ΔQ value that exceeds the threshold ΔQ value may indicate that a logical one value was stored at the capacitor 102 prior to performing the read operation. A sensed ΔQ value that fails to exceed the threshold ΔQ value may indicate that a logical zero value was stored at the capacitor 102 prior to performing the read operation, as further described with reference to FIG. 15.

As illustrated in FIG. 14, performing the read operation may change the polarization state of the bi-stable asymmetric crystalline material of the single ferroelectric layer 114. Because the logical value (e.g., the logical one value) stored at the capacitor 102 prior to performance of the read operation is lost due to the read operation, the read operation may be referred to as a “destructive” read operation. To maintain the logical value stored at the capacitor 102 after performing the read operation, a writeback operation may be performed after performing the read operation. For example, when the sensed ΔQ value exceeds the threshold ΔQ value, the writeback operation may be performed. The writeback operation may write a logical one value at the capacitor 102, as described with reference to FIG. 13. The writeback operation may thus compensate for the destructive read operation.

FIG. 14 thus illustrates an embodiment 1400 of performing a read operation at the DRAM cell 400 of FIG. 4. Because the capacitor 102 stored a logical one value prior to performance of the read operation, applying Vread 1430 that exceeds the positive switching voltage Vc may cause a change to the polarization state of the bi-stable asymmetric crystalline material of the single ferroelectric layer 114. The sense amplifier coupled to the capacitor 102 may sense the ΔQ value and a determination that a logical one value was stored at the capacitor 102 prior to performance of the read operation may be based on the sensed ΔQ value exceeding a threshold ΔQ value. To maintain the logical one value stored at the capacitor 102, a writeback operation may be performed after performing the read operation.

Referring to FIG. 15, a diagram of a second illustrative embodiment of performing a read operation at the DRAM cell 400 of FIG. 4 is shown and designated 1500. Although performance of the read operation is described with respect to the DRAM cell 400 of FIG. 4, in other embodiments the read operation may be performed on any of the DRAM cells 100-1100 of FIGS. 1-11.

In a particular embodiment, the capacitor 102 may store a logical zero value prior to performance of the read operation. For example, the bi-stable asymmetric crystalline material of the single ferroelectric layer 114 may be polarized in the first polarization state associated with the electric dipole of the bi-stable asymmetric crystalline material having an upward orientation, as indicated by the upward orientation of the polarity 1510. When the polarity 1510 has the upward orientation, a voltage Vox 1512 across the high-k dielectric layer 116 may have a positive value, as indicated by the downward direction of Vox 1512 in FIG. 15 prior to performance of the read operation.

During the read operation in FIG. 15, a read voltage Vread 1530 that exceeds a positive switching voltage Vc of the bi-stable asymmetric crystalline material may be applied to the capacitor 102. Application of Vread 1530 may shift the polarization of the bi-stable asymmetric crystalline material along a hysteresis curve 1520 from a polarization state 1522 representing storage of the logical one zero to a temporary polarization state 1524. Shifting from the polarization state 1522 to the temporary polarization state 1524 may be associated with a small ΔP value (as compared to the ΔP value of FIG. 14). After Vread 1530 is applied, the polarization may return to the polarization state 1522 associated with storage of a logical zero value. For example, after application of Vread 1530 (e.g., after performing the read operation), the polarity 1510 retains the upward orientation (e.g., the electric dipole of the bi-stable asymmetric crystalline material retains an upward direction) and the voltage Vox retains a positive value, as indicated by the downward direction of Vox.

Because application of Vread 1530 does not cause the polarization state of the bi-stable asymmetric crystalline material to change, a small ΔP value may be associated with performing the read operation at a DRAM cell that stores a logical zero value. Due to the small ΔP value, the sense amplifier may sense a small ΔQ value during performance of the read operation. The ΔQ value sensed by the sense amplifier may be compared to the threshold ΔQ value associated with a change in polarization states to determine whether a logical one value was stored at the capacitor 102 prior to performance of the read operation. For example, a sensed ΔQ value that fails to exceed the threshold ΔQ value may indicate that a logical zero value was stored at the capacitor 102 prior to performing the read operation. Because performing the read operation does not cause a polarization state to change when a logical zero value is stored at the capacitor 102 prior to performance of the read operation, a writeback operation may not be performed when the sensed ΔQ value fails to exceed the threshold ΔQ value.

FIG. 15 thus illustrates an embodiment 1500 of performing a read operation at the DRAM cell 400 of FIG. 4. Because the capacitor 102 stored a logical zero value prior to performance of the read operation, applying Vread 1530 that exceeds the positive switching voltage Vc may not cause a change to the polarization state of the bi-stable asymmetric crystalline material of the single ferroelectric layer 114. The sense amplifier coupled to the capacitor 102 may sense the ΔQ value and a determination that a logical zero value was stored at the capacitor 102 prior to performance of the read operation may be based on the sensed ΔQ failing to exceed the threshold ΔQ value.

Although the read voltage applied in FIGS. 14 and 15 exceeds the positive switching voltage Vc, in another particular embodiment the read operations may be performed by applying a read voltage that is less than a negative switching voltage −Vc (e.g., having a magnitude that is greater than a magnitude of the negative switching voltage −Vc). In this embodiment, performing the read operation may cause a logical zero value to be stored at the capacitor 102. Accordingly, a logical zero value stored at the capacitor 102 prior to performance of the read operation may be associated with a small ΔQ value during the read operation, and a logical zero value stored at the capacitor 102 prior to performance of the read operation may be associated with a large ΔQ value during the read operation. In this embodiment, a writeback operation may be performed to maintain the logical zero value when the sensed ΔQ value exceeds the threshold ΔQ value. In other embodiments, the bi-stable asymmetric crystalline material may be associated with hysteresis curves having a different shape. In these embodiments, the sensed ΔQ values may be compared to different threshold ΔQ values based on the different hysteresis curves. In some embodiments, the hysteresis curves may have “flatter” shapes and the read operations may not be destructive. Although FIGS. 12-15 show negative polarization corresponding to a logical zero value and positive polarization corresponding to a logical one value, in other embodiments, negative polarization may correspond to a logical one value and positive polarization may correspond to a logical zero value.

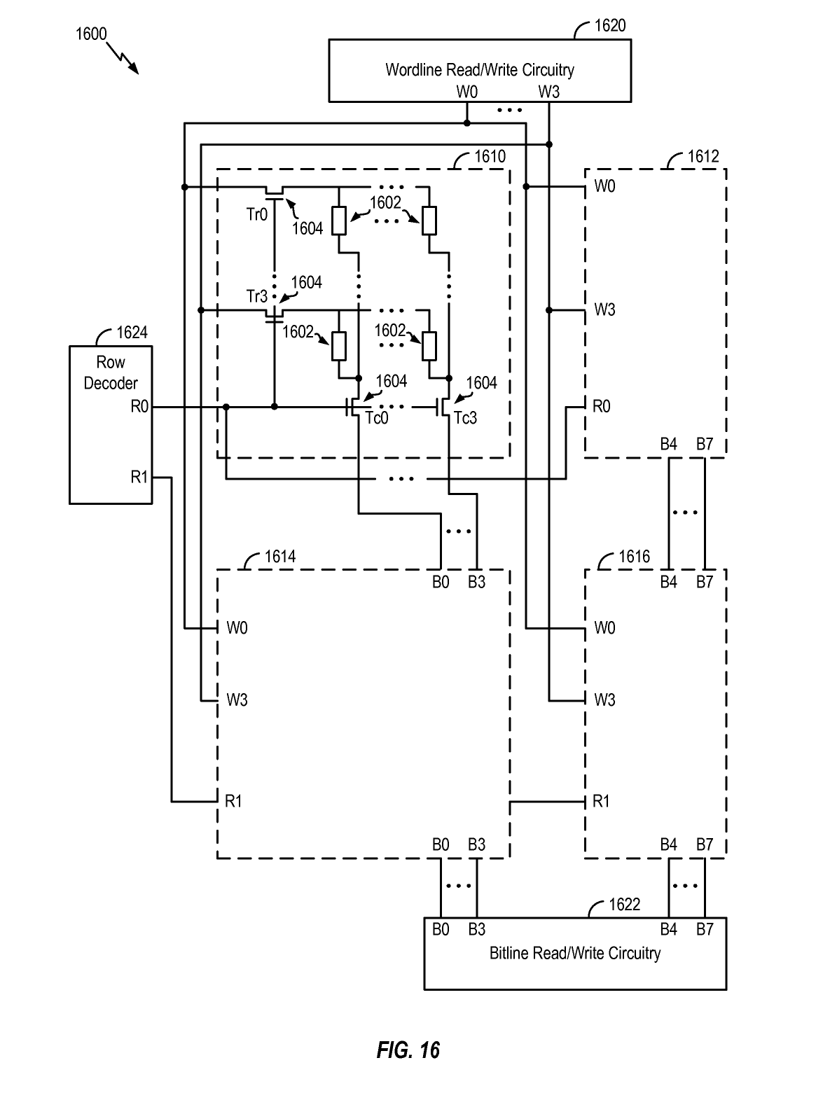

Referring to FIG. 16, a particular embodiment of a memory array is illustrated and designated 1600. The memory array 1600 may be divided into multiple array blocks. For example, the memory array 1600 may be divided into four array blocks 1610-1616. Each of the array blocks 1610 may include multiple DRAM cells 1602 and multiple isolation transistors 1604. The DRAM cells 1602 may include or correspond to any of the DRAM cells 100-1100 of FIGS. 1-11 and may be 1S1C DRAM cells. The isolation transistors 1604 may be referred to as “hybrid row and column transistor selectors.”

As illustrated in FIG. 16, the DRAM cells 1602 included in array block 1610 may be configured in rows and columns. In a particular embodiment, the array block 1610 may include sixteen DRAM cells 1602. Additionally, the array block 1610 may include eight isolation transistors 1604, which may include four wordline isolation transistors Tr0-Tr3 and four bitline isolation transistors Tc0-Tc3. The wordline isolation transistors Tr0-Tr3 may be coupled between wordlines and the DRAM cells 1602 and may be responsive to a voltage on the row decoder line. The bitline isolation transistors Tc0-Tc3 may be coupled between bitlines and the DRAM cells 1602 and may be responsive to the voltage on the row decoder line. The array blocks 1612-1616 may include similar components and may be configured in a similar arrangement as the array block 1610, and are not illustrated in FIG. 16 for convenience. In other embodiments, the memory array 1600 may be divided into different numbers of array blocks, each array block may include a different number of DRAM cells 1602 and/or a different number of isolation transistors 1604, or a combination thereof.

Wordlines and bitlines may be routed to rows and columns, respectively, of the array blocks 1610-1616. In a particular embodiment the memory array 1600 may include four wordlines W0-W3 and eight bitlines B0-B7 (wordlines W0 and W3 and bitlines B0, B3, B4, and B7 are illustrated in FIG. 16 for convenience). In other embodiments, different numbers of wordlines and bitlines may be used based on the number of rows and columns in the array blocks.

As illustrated in FIG. 16, each wordline may be provided to a corresponding row of each of the array blocks 1610-1616. Bitlines B0-B3 may be provided to the array blocks 1610 and 1614 (e.g., a first column of array blocks) and bitlines B4-B7 may be provided to the array blocks 1612 and 1616 (e.g., a second column of array blocks). Row decoder line R0 may be provided to the array blocks 1610 and 1612 (e.g., a first row of array blocks) and row decoder line R1 may be provided to the array blocks 1614 and 1616 (e.g., a second row of array blocks). Wordline read/write circuitry 1620 may be configured to charge a wordline during a read operation or during a write operation to select a particular row of the DRAM cells 1602. Bitline read-write circuitry 1622 may be configured to charge one or more bitlines during the write operation to select a particular column of the DRAM cells 1602. Bitline read-write circuitry 1622 may be further configured to sense a charge on a particular bitline during the read operation. Row decoder 1624 may be configured to charge a particular row decoder line during a read operation or during a write operation to select a particular row of array blocks.

During operation, a read operation may be performed on a particular DRAM cell 1602 in a first row and in a first column of the array block 1610. The wordline read/write circuitry 1620 may charge (e.g., assert) the wordline W0 associated with the first row and may discharge (e.g., de-assert) the wordlines W1-W3. The bitline read/write circuitry 1622 may sense a charge on the bitline B0 associated with the first column of the array block 1610 and may discharge (e.g., de-assert) the bitlines B1-B3 associated with the other columns of the array block 1610 and the bitlines B4-B7 corresponding to a second column of array blocks (e.g., array blocks 1612 and 1616). The row decoder 1624 may charge (e.g., assert) the row decoder line R0 to select a first row of array blocks (e.g., the array blocks 1610 and 1612). When the row decoder line R0 is asserted, the isolation transistors 1604 may be enabled and the read operation may be performed at the selected DRAM cell 1602 of the array block 1610, as described with reference to FIGS. 14-15.

Because the DRAM cells 1602 of the array block 1614 are also coupled between the wordlines W0-W3 and the bitlines B0-B3, the DRAM cells 1602 of the array block 1614 may provide one or more current paths (e.g., “sneak paths”) through which leakage current may flow between the word lines W0-W3 and the bitlines B0-B3. To reduce an impact of the leakage current (e.g., “sneak path charge leakage”) on the charge sensing performed during the read operation, the row decoder 1624 may de-assert the row decoder line R1 to deselect a second row of array blocks (e.g., array blocks 1614 and 1616). When the row decoder line R1 is not asserted, the isolation transistors 1604 of the array block 1614 may be disabled and may isolate the wordlines W0-W3 from the bitlines B0-B3 in the array block 1614, which may reduce or eliminate the current paths (e.g., the sneak paths) in the array block 1614 during the read operation. Accordingly, leakage current flowing through the array block 1614 may be reduced or eliminated and the impact of sneak path charge leakage on the read operation may be reduced. An effect of leakage current during a write operation may be reduced in a similar manner.

Thus, the memory array 1600 having the hybrid row and column transistor selectors (e.g., the isolation transistors 1604) may reduce an effect of leakage current (e.g., sneak path current) on a read operation or a write operation, as compared to other memory arrays. For example, by de-selecting one or more other rows of array blocks during a read operation or a write operation, isolation transistors 1604 in other array blocks in a same column of array blocks as a selected array block may be disabled. Disabling the isolation transistors may isolate the wordlines from the bitlines and may reduce or prevent leakage current from flowing through the other array blocks in the same column. Reducing the leakage current may increase performance of read operations and write operations.

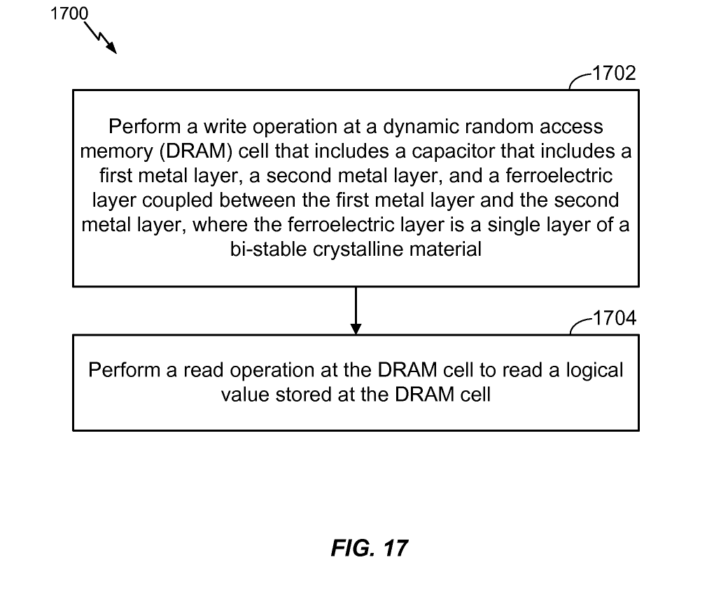

Referring to FIG. 17, a particular embodiment of a method 1700 of performing a write operation and a read operation at a DRAM cell including a capacitor that includes a single ferroelectric layer of a bi-stable asymmetric crystalline material is shown. The method 1700 may be performed at any of the DRAM cells 100-1100 of FIGS. 1-11.

The method 1700 includes performing a write operation a DRAM cell that includes a first metal layer, a second metal layer, and a ferroelectric layer coupled between the first metal layer and the second metal layer, at 1702. For example, with reference to FIG. 1, the write operation may be performed at the DRAM cell 100 that includes the first electrode 110, the second electrode 112, and the single ferroelectric layer 114. As another example, with reference to FIG. 4, the write operation may be performed at the DRAM cell 400 that includes the first electrode 110, the second electrode 112, the single ferroelectric layer 114, and the high-k dielectric layer 116. As yet another example, with reference to FIG. 6, the write operation may be performed at the DRAM cell 600 that includes the bottom electrode 610, the top electrode 612, and the single ferroelectric layer 614. The write operation may write a logical zero value or a logical one value, as described with reference to FIG. 12 or FIG. 13, respectively. The ferroelectric layer may be a single layer of a bi-stable asymmetric crystalline material. For example, the bi-stable asymmetric crystalline material may include or correspond to the bi-stable asymmetric crystalline material of the single ferroelectric layer 114 of FIG. 1. In a particular embodiment, the bi-stable asymmetric crystalline material may include hafnium oxide or doped hafnium oxide.

The method 1700 also includes performing a read operation at the DRAM cell to read a logical value stored at the DRAM cell, at 1704. For example, a read operation may be performed at the DRAM cell 100 of FIG. 1 or the DRAM cell 600 of FIG. 6 to read a logical value, as non-limiting examples. The read operation may read a logical zero value or a logical one value stored at the capacitor, as described with reference to FIG. 14 or FIG. 15, respectively. In a particular embodiment, the DRAM cell may be selected for performance of the read operation or for performance of the write operation based on a voltage applied to a selector included in the DRAM cell. For example, the DRAM cell 100 may be selected based on a voltage applied to the selector 104 of FIG. 1. In a particular embodiment, the selector 104 may include a voltage-dependent resistor layer, such as the selector layer 124 of FIGS. 2-5, the selector layer 624 of FIGS. 6-9, or the selector layer 1024 of FIGS. 10 and 11. The selector may be coupled to or integrated within the capacitor. For example, the selector 104 may be separate from (e.g., external to) and coupled to the capacitor 102, as illustrated in FIG. 2, or the selector 104 may be integrated within the capacitor 102, as illustrated in FIG. 3.

In a particular embodiment, when the logical value is a logical one value, performing the write operation may include applying a first write voltage to the capacitor to polarize the bi-stable asymmetric crystalline material to a first polarization state. For example, with reference to FIG. 1, a write voltage that exceeds a positive switching voltage Vc may be applied to the capacitor 102 to change the polarization state to the first polarization state (e.g., to orient an electric dipole in the upward direction) associated with storage of the logical zero value. In this embodiment, the write operation may include or correspond to the write operation of FIG. 12. In another particular embodiment, when the logical value is a logical zero value, performing the write operation may include applying a second write voltage to the capacitor to polarize the bi-stable asymmetric crystalline material to a second polarization state. For example, with reference to FIG. 1, a write voltage that is less than a negative switching voltage −Vc may be applied to the capacitor 102 to change the polarization state to the second polarization state (e.g., to orient an electric dipole in the downward direction) associated with storage of the logical one value. In this embodiment, the write operation may include or correspond to the write operation of FIG. 13.

In a particular embodiment, the method 1700 further includes applying a read voltage to the capacitor and sensing a change in charge of the capacitor based on an application of the read voltage. For example, with reference to FIGS. 14 and 15, a read voltage that exceeds a positive switching voltage may be applied to the capacitor and a ΔQ value associated with a charge pulse triggered by application of the read voltage may be sensed at a sense amplifier. The magnitude of the change in charge may indicate the logical value stored at the DRAM cell prior to applying the read voltage. For example, a large ΔQ value may indicate a logical one value was stored at the capacitor of the DRAM cell prior to performing the read operation, as described with reference to FIG. 14. As another example, a small ΔQ value may indicate a logical zero value was stored at the capacitor prior to performing the read operation, as described with reference to FIG. 15. The method 1700 may further include performing a writeback operation after performing the read operation when the logical value stored at the DRAM cell prior to applying the read voltage is a logical one value. For example, the read operation may be a destructive read operation that changes a polarization state of the bi-stable asymmetric crystalline material to the first polarization state associated with storage of a logical zero value, as described with reference to FIG. 14. In order to maintain a logical one value at the capacitor, a writeback operation (e.g., a write operation to write a logical one value) may be performed after the read operation.

The method 1700 may enable performance of read operations and write operations at a DRAM cell that includes a capacitor with a single ferroelectric layer including a bi-stable asymmetric crystalline material. Because a logical value stored at the capacitor is represented by a polarization state of the bi-stable asymmetric crystalline material, the logical value may not be degraded by leakage current. Thus, a logical value written by the method 1700 may not be lost over time due to leakage current.

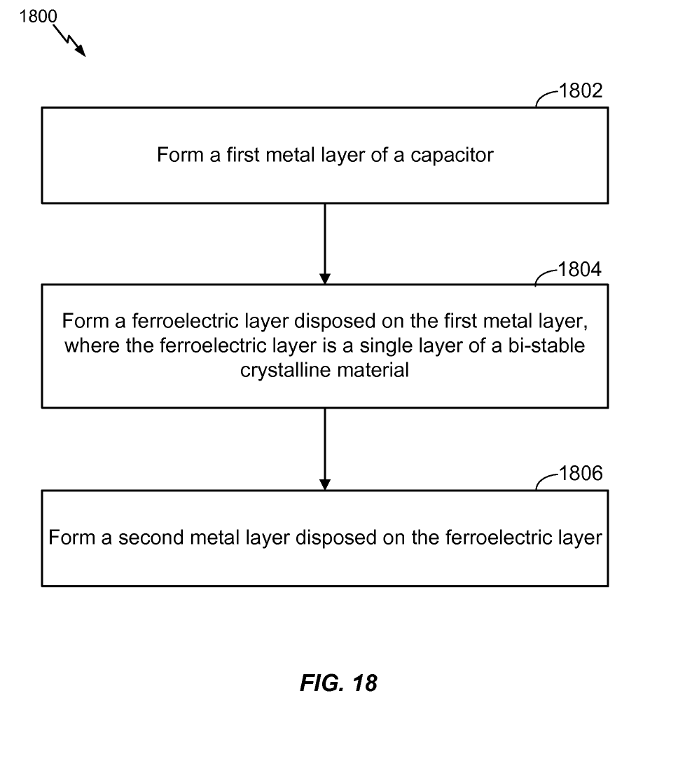

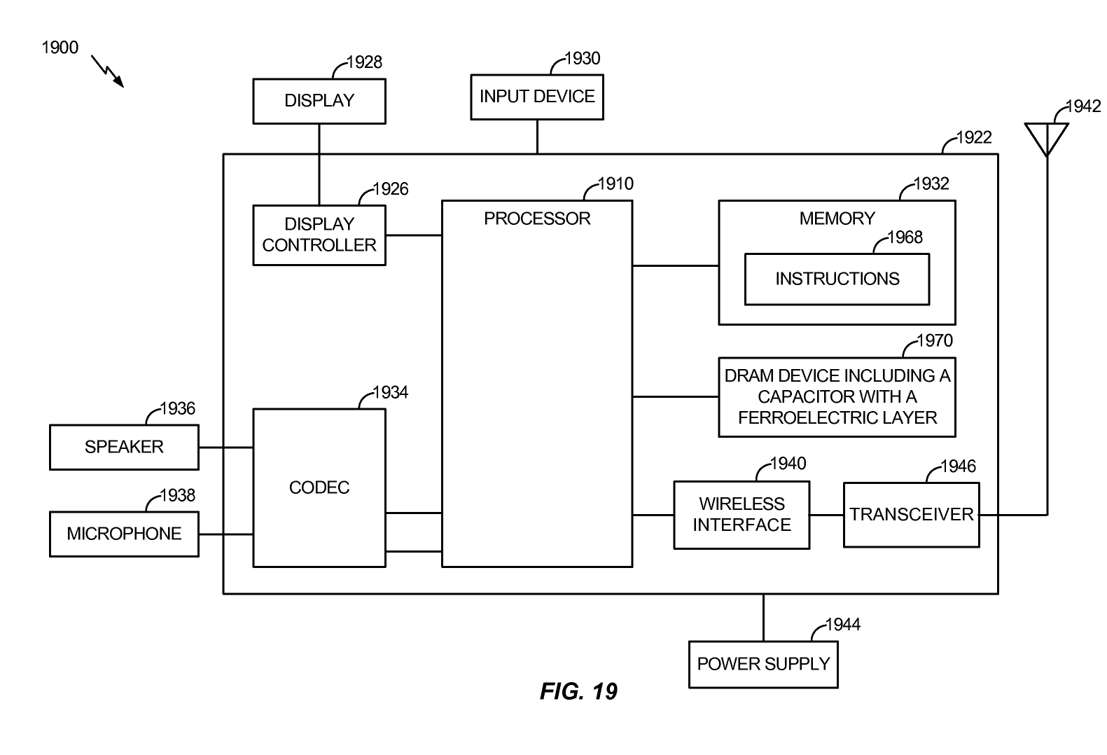

Referring to FIG. 18, a particular embodiment of a method 1800 of forming a capacitor that includes a single ferroelectric layer of a bi-stable asymmetric crystalline material is shown. The method 1800 may be performed to form any of the capacitors 102, 602, or 1002 of FIGS. 1-11.

The method 1800 includes forming a first metal layer of a capacitor, at 1802. For example, the first electrode 110 of the capacitor 102 of FIG. 1 may be formed on a semiconductor die via a first metal deposition process.

The method 1800 includes forming a ferroelectric layer disposed on the first metal layer, at 1804. For example, the single ferroelectric layer 114 may be formed on the first electrode 110 of FIG. 1 via a ferroelectric thin film deposition process. The ferroelectric layer may be a single layer of a bi-stable asymmetric crystalline material. For example, the single ferroelectric layer 114 of FIG. 1 may be formed using a bi-stable asymmetric crystalline material, such as hafnium oxide or doped hafnium oxide. In a particular embodiment, a selector layer (e.g., a voltage-dependent resistor layer having a nonlinear, voltage-dependent resistance) may be formed on the on the first metal layer. For example, the selector layer 124 may be formed on the first electrode 110 of FIG. 3. In another particular embodiment, a high-k dielectric layer may be formed prior to forming the ferroelectric layer. For example, the high-k dielectric layer 116 may be formed on the first electrode 110 of FIG. 4 or the high-k dielectric layer 116 may be formed on the selector layer 124 of FIG. 5.

The method 1800 further includes forming a second metal layer disposed on the ferroelectric layer, at 1806. For example, the second electrode 112 of the capacitor 102 of FIG. 1 may be formed via a second metal deposition process.

The method 1800 may enable formation of a capacitor with a single ferroelectric layer that includes a bi-stable asymmetric crystalline material. Because a logical value stored at the capacitor is represented by a polarization state of the bi-stable asymmetric crystalline material, the capacitor formed using the method 1800 may be formed having a smaller size as compared to other DRAM capacitors without causing a retention time of the capacitor to fall below a retention time threshold. For example, the capacitor formed using the method 1800 may be scaled to process nodes less than or equal to 20 nm.

A memory device including a DRAM cell that includes a capacitor formed in accordance with the method 1800 of FIG. 18 may be manufactured using a fabrication process. A processor and a memory may initiate and/or control the fabrication process. The memory may include executable instructions such as computer-readable instructions or processor-readable instructions. The executable instructions may include one or more instructions that are executable by a computer, such as a computer that includes the processor and the memory.

The fabrication process may be implemented by a fabrication system that is fully automated or partially automated. For example, the fabrication process may be automated according to a schedule. The fabrication system may include fabrication equipment (e.g., processing tools) to perform one or more operations to form a memory device. For example, the fabrication equipment may be configured to deposit one or more materials (e.g., layers), etch the one or more layers, deposit an etch stop layer, form a via layer, perform planarization, etc.

The fabrication system (e.g., an automated system that performs the fabrication process) may have a distributed architecture (e.g., a hierarchy). For example, the fabrication system may include one or more processors, one or more memories, and/or controllers that are distributed according to the distributed architecture. The distributed architecture may include a high-level processor that controls or initiates operations of one or more low-level systems. For example, a high-level portion of the fabrication system may include one or more processors and the low-level systems may each include or may be controlled by one or more corresponding controllers. A particular controller of a particular low-level system may receive one or more instructions (e.g., commands) from a particular high-level system, may issue sub-commands to subordinate modules or process tools, and may communicate status data to the particular high-level system. Each of the one or more low-level systems may be associated with one or more corresponding pieces of fabrication equipment (e.g., processing tools). In a particular embodiment, the fabrication system may include multiple processors that are distributed in the fabrication system. For example, a controller of a low-level system component may include one or more processors.

To illustrate, a processor of the fabrication system may be a part of a high-level system, subsystem, or component of the fabrication system. In another embodiment, the processor of the fabrication system includes or is associated with distributed processing at various levels and components of a fabrication system.

Thus, a processor of the fabrication system may include or have access to processor-executable instructions that, when executed by the processor, cause the processor to initiate or control formation of a memory device, the memory device formed by forming a first metal layer of a capacitor, by forming a ferroelectric layer disposed on the first metal layer, the ferroelectric layer including a single layer of a bi-stable asymmetric crystalline material, and by forming a second metal layer disposed on the ferroelectric layer. The memory device may include DRAM having a three-dimensional (3D) memory architecture. The DRAM may include multiple DRAM cells that include a capacitor formed as described above. For example, the DRAM cells may be formed by one or more deposition tools, such as a molecular beam epitaxial growth tool, a flowable chemical vapor deposition (FCVD) tool, a conformal deposition tool, or a spin-on deposition tool, and by one or more etch removal tools, such as a chemical removal tool.

The executable instructions included in the memory of the fabrication system may enable the processor of the fabrication system to initiate formation of a memory device, such as a memory device that includes at least one of the DRAM cells 100-1100 of FIGS. 1-11. In a particular embodiment, the memory of the fabrication system stores computer-executable instructions that are executable by the processor to cause the processor to initiate formation of the capacitor 102 of FIG. 1, in accordance with the method 1800 of FIG. 18. For example, the computer executable instructions may be executable to cause the processor to initiate formation of the capacitor by forming a first metal layer of a capacitor, by forming a ferroelectric layer disposed on the first metal layer, the ferroelectric layer including a single layer of a bi-stable asymmetric crystalline material, and by forming a second metal layer disposed on the ferroelectric layer.

Referring to FIG. 19, a particular illustrative embodiment of a wireless communication device is depicted and generally designated 1900. The device 1900 includes a processor 1910, such as a digital signal processor, coupled to a memory 1932 and a DRAM device 1970. The DRAM device 1970 may include a capacitor with a ferroelectric layer. For example, the DRAM device 1970 may include the capacitor 102 that includes the single ferroelectric layer 114 of FIGS. 1-5, the capacitor 602 that includes the single ferroelectric layer 614 of FIGS. 6-9, or the capacitor 1002 that includes the single ferroelectric layer 1014 of FIGS. 10 and 11. The processor 1910 may be configured to execute software (e.g., a program of one or more instructions 1968) stored in the memory 1932. For example, the processor 1910 may be configured to execute the one or more instructions 1968 to perform read operations and/or write operations at the DRAM device 1970. In a particular embodiment, the DRAM device 1970 may provide faster access times than the memory 1932 and may be used as a cache.

In a particular embodiment, the processor 1910 may be configured to execute the computer executable instructions stored at a non-transitory computer-readable medium, such as the memory 1932, to perform a write operation at a DRAM cell that includes a capacitor that includes a first metal layer, a second metal layer, and a ferroelectric layer coupled between the first metal layer and the second metal layer. For example, the processor 1910 may perform a write operation at a DRAM cell of the DRAM device 1970. The ferroelectric layer may include a single layer of bi-stable asymmetric crystalline material, such as hafnium oxide or doped hafnium oxide. In a particular embodiment, performing the write operation may include causing a write voltage to be applied to the capacitor to polarize the bi-stable asymmetric crystalline material to a polarization state associated with the logical value, as described with reference to FIGS. 12 and 13. The computer executable instructions may be further executable by the processor 1910 to perform a read operation at the DRAM cell to read a logical value stored at the DRAM cell. For example, the processor 1910 may perform a read operation at a DRAM cell of the DRAM device 1970 to read a logical value stored at the DRAM cell.

FIG. 19 also illustrates that a display controller 1926 may be coupled to the processor 1910 and to a display 1928. A coder/decoder (CODEC) 1934 can also be coupled to the processor 1910. A speaker 1936 and a microphone 1938 can be coupled to the CODEC 1934. FIG. 19 further shows that a wireless interface 1940 may be coupled to the processor 1910 and to an antenna 1942. For example, the wireless interface 1940 may be coupled to the antenna 1942 via a transceiver 1946, such that wireless data received via the antenna 1942 and the wireless interface 1940 may be provided to the processor 1910.

In a particular embodiment, the processor 1910, the display controller 1926, the memory 1932, the CODEC 1934, and the wireless interface 1940 are included in a system-in-package or system-on-chip device 1922. In a particular embodiment, an input device 1930 and a power supply 1944 are coupled to the system-on-chip device 1922. Moreover, in a particular embodiment, as illustrated in FIG. 19, the display device 1928, the input device 1930, the speaker 1936, the microphone 1938, the antenna 1942, and the power supply 1944 are external to the system-on-chip device 1922. However, each of the display device 1928, the input device 1930, the speaker 1936, the microphone 1938, the antenna 1942, and the power supply 1944 can be coupled to one or more components of the system-on-chip device 1922, such as one or more interfaces or controllers.

In conjunction with the described embodiments, an apparatus includes first conductive means and second conductive means. For example, the first conductive means may include the first electrode 110 of FIGS. 1-5, the bottom electrode 610 of FIGS. 6-9, the bottom electrode 1010 of FIGS. 10 and 11, one or more other conductive materials, or any combination thereof. The second conductive means may include the second electrode 112 of FIGS. 1-5, the top electrode 612 of FIGS. 6-9, the top electrode 1012 of FIGS. 10 and 11, one or more other conductive materials, or any combination thereof.

The apparatus also includes means for isolating the first conductive means from the second conductive means. The means for isolating may include a ferroelectric layer that includes a single layer of a bi-stable asymmetric crystalline material. For example, the means for isolating may include the single ferroelectric layer 114 of FIGS. 1-5, the single ferroelectric layer 614 of FIGS. 6-9, the single ferroelectric layer 1014 of FIGS. 10 and 11, or any combination thereof. In a particular embodiment, the bi-stable asymmetric crystalline material may include hafnium oxide or doped hafnium oxide, as described with reference to FIG. 1.

In a particular embodiment, a DRAM cell may include the first conductive means, the second conductive means, and the means for isolating. For example, the first conductive means, the second conductive means, and the means for isolating may be integrated within any of the DRAM cells 100-1100 of FIGS. 1-11. In another particular embodiment, the apparatus may include means for selecting the DRAM cell. For example, the means for selecting the DRAM cell may include the selector layer 124 of FIGS. 1-5, the selector layer 624 of FIGS. 6-9, the selector layer 1024 of FIGS. 10 and 11, or any combination thereof. A resistance of the means for selecting may vary based on a voltage applied to the means for selecting.

One or more of the disclosed embodiments may be implemented in a system or an apparatus, such as the device 1900, that may include a communications device, a fixed location data unit, a mobile location data unit, a mobile phone, a cellular phone, a satellite phone, a computer, a tablet, a portable computer, or a desktop computer. Additionally, the device 1900 may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, any other device that stores or retrieves data or computer instructions, or a combination thereof. As another illustrative, non-limiting example, the system or the apparatus may include remote units, such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof.

Although one or more of FIGS. 1-18 may illustrate systems, apparatuses, and/or methods according to the teachings of the disclosure, the disclosure is not limited to these illustrated systems, apparatuses, and/or methods. Embodiments of the disclosure may be suitably employed in any device that includes integrated circuitry including memory, a processor, and on-chip circuitry.

Those of skill in the art would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient (e.g., non-transitory) storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

1. A memory cell comprising:
a capacitor comprising:
a first metal layer;
a second metal layer; and
a ferroelectric layer disposed between the first metal layer and the second metal layer, wherein the ferroelectric layer is a single layer of a bi-stable asymmetric crystalline material.

2. The memory cell of claim 1, wherein a first polarization state of the bi-stable asymmetric crystalline material represents a first logical value, and wherein a second polarization state of the bi-stable asymmetric crystalline material represents a second logical value.

3. The memory cell of claim 1, wherein the bi-stable asymmetric crystalline material comprises hafnium oxide.

4. The memory cell of claim 3, wherein the hafnium oxide is doped with zirconium, silicon, or aluminum.

5. The memory cell of claim 1, further comprising a high-k dielectric layer disposed between the first metal layer and the second metal layer.

6. The memory cell of claim 1, wherein the memory cell is a dynamic random access memory (DRAM) cell.

7. The memory cell of claim 1, further comprising a selector layer.

8. The memory cell of claim 7, further comprising a selector coupled to the capacitor, wherein the selector includes the selector layer.

9. The memory cell of claim 8, wherein the selector comprises a third electrode, a fourth electrode, and the selector layer, and wherein the selector layer is disposed between the third electrode and the fourth electrode.

10. The memory cell of claim 8, wherein the selector layer comprises a voltage-dependent resistor layer.

11. The memory cell of claim 7, further comprising a high-k dielectric layer disposed between the first metal layer and the second metal layer.

12. The memory cell of claim 7, wherein the selector layer is formed as one or more layers of the capacitor.

13. The memory cell of claim 12, wherein the selector layer is disposed between the ferroelectric layer and the first metal layer.

14. The memory cell of claim 7, wherein the capacitor and the selector layer are integrated in a memory device having a three-dimensional memory architecture.

15. The memory cell of claim 7, wherein the capacitor and the selector layer are integrated in a semiconductor die that includes a processor or an application-specific integrated circuit.

16. The memory cell of claim 15, wherein the capacitor and the selector layer are formed in a trench within one or more intermetal dielectric layers of the semiconductor die.

17. The memory cell of claim 7, wherein the capacitor and the selector are integrated within a memory array that includes multiple array blocks, and wherein a transistor is configured to isolate a wordline from a bitline in an array block of the multiple array blocks to reduce an impact of sneak path charge leakage on sensing operations.

18. A method comprising:
performing a write operation at a dynamic random access memory (DRAM) cell that includes a capacitor that includes a first metal layer, a second metal layer, and a ferroelectric layer coupled between the first metal layer and the second metal layer, wherein the ferroelectric layer is a single layer of a bi-stable asymmetric crystalline material; and
performing a read operation at the DRAM cell to read a logical value stored at the DRAM cell.

19. The method of claim 18, wherein, when the logical value is a logical one value, performing the write operation comprises applying a first write voltage to the capacitor to polarize the bi-stable asymmetric crystalline material to a first polarization state.

20. The method of claim 18, wherein the DRAM is configured to store a logical one value in response to application of a first write voltage to the capacitor to polarize the bi-stable asymmetric crystalline material to a first polarization state, and wherein, when the logical value is a logical zero value, performing the write operation comprises applying a second write voltage to the capacitor to polarize the bi-stable asymmetric crystalline material to a second polarization state.

21. The method of claim 18, wherein performing the read operation comprises:
applying a read voltage to the capacitor; and
sensing a change in charge of the capacitor based on application of the read voltage, wherein a magnitude of the change in charge indicates the logical value stored at the DRAM cell prior to applying the read voltage.

22. The method of claim 21, further comprising performing a writeback operation after performing the read operation when the logical value stored at the DRAM cell prior to applying the read voltage is a logical one value.

23. The method of claim 18, wherein the bi-stable asymmetric crystalline material is formed as a thin film layer that comprises hafnium oxide.

24. The method of claim 18, wherein the DRAM cell is selected for performance of the read operation or performance of the write operation based on a voltage applied to a selector included in the DRAM cell, and wherein the selector is coupled to or integrated within the capacitor.

25. An apparatus comprising:
first conductive means for applying voltage;
second conductive means for applying voltage; and
means for isolating the first conductive means from the second conductive means, wherein the means for isolating includes a ferroelectric layer that includes a single layer of a bi-stable asymmetric crystalline material.

26. The apparatus of claim 25, wherein a capacitor of a dynamic random access memory (DRAM) cell comprises the first conductive means, the second conductive means, and the means for isolating, and wherein the bi-stable asymmetric crystalline material comprises hafnium oxide.

27. The apparatus of claim 26, further comprising means for selecting the DRAM cell, wherein a resistance of the means for selecting varies based on a voltage applied to the means for selecting.

28. A non-transitory computer-readable medium comprising instructions that, when executed by a processor, cause the processor to:
perform a write operation at a dynamic random access memory (DRAM) cell that includes a capacitor that includes a first metal layer, a second metal layer, and a ferroelectric layer coupled between the first metal layer and the second metal layer, wherein the ferroelectric layer is a single layer of a bi-stable asymmetric crystalline material; and
perform a read operation at the DRAM cell to read a logical value stored at the DRAM cell.

29. The non-transitory computer-readable medium of claim 28, wherein the processor is caused to perform the write operation by applying a write voltage to the capacitor to polarize the bi-stable asymmetric crystalline material to a polarization state associated with the logical value.

30. The non-transitory computer-readable medium of claim 28, wherein the processor is caused to perform the write operation and the read operation at a articular DRAM cell that includes a articular bi-stable asymmetric crystalline material that comprises hafnium oxide or doped hafnium oxide.
